(19) United States
(12) Patent Application Publication
(10) Pub. No.: US 2026/0121754 A1
(43) Pub. Date: Apr. 30, 2026

(54) PHOTONIC WAFER SCALE INTERPOSER WITH ANGLED BEAM GRATING COUPLERS

(71) Applicant: Volantis Semiconductor, Inc., Portland, OR (US)

(72) Inventor: Tapabrata Ghosh, San Francisco, CA (US)

(73) Assignee: Volantis Semiconductor, Inc., Portland, OR (US)

(21) Appl. No.: 19/188,057

(22) Filed: Apr. 24, 2025

Related U.S. Application Data
(63) Continuation-in-part of application No. 19/177,834, filed on Apr. 14, 2025.
Application No. 19/177,834 is a continuation-in-part of application No. 19/093,546, filed on Mar. 28, 2025.
Application No. 19/093,546 is a continuation-in-part of application No. 19/079,851, filed on Mar. 14, 2025.
Application No. 19/079,851 is a continuation-in-part of application No. 19/056,456, filed on Feb. 18, 2025.
Application No. 19/056,456 is a continuation-in-part of application No. 19/023,647, filed on Jan. 16, 2025.
Application No. 19/023,647 is a continuation-in-part of application No. 18/978,188, filed on Dec. 12, 2024.
Application No. 18/978,188 is a continuation-in-part of application No. 18/958,107, filed on Nov. 25, 2024.
Application No. 18/958,107 is a continuation-in-part of application No. 18/940,944, filed on Nov. 8, 2024.
(60) Provisional application No. 63/714,353, filed on Oct. 31, 2024.
(60) Provisional application No. 63/720,216, filed on Nov. 14, 2024.
(60) Provisional application No. 63/750,817, filed on Jan. 29, 2025.
(60) Provisional application No. 63/750,822, filed on Jan. 29, 2025.

(51) Int. Cl. H04B 10/50; G02B 6/12; G02B 6/122; H04B 10/564

(52) U.S. Cl. CPC H04B 10/503; G02B 6/12004; G02B 6/1228; H04B 10/564; G02B 2006/12107; G02B 2006/12121; G02B 2006/12145; G02B 2006/12147

(57) ABSTRACT

Techniques for sending data are disclosed. A photonic wafer-scale interposer (PWSI) is accessed. A front side of the PWSI is bonded to a plurality of chiplets. The chiplets include at least one surface-emitting light source, a first chiplet, and a second chiplet. The PWSI includes a plurality of waveguides. Data is sent, by the first chiplet, to a first surface-emitting light source. Light is emitted by the first surface-emitting light source. The light that was emitted is based on the data that was sent. The emitting includes angling the light by an optical element (OE). The light that was angled from the first surface-emitting light source is coupled, by a grating coupler within the PWSI, to a first waveguide. The data that was sent is received by the second chiplet. The receiving is based on the light that was coupled to the first waveguide.

### RELATED APPLICATIONS

This application is a continuation-in-part of U.S. patent application “Back Side Power Delivery For Wafer-Scale Integration With An Isometric Grid Array With Compression Pins” Ser. No. 19/177,834, filed Apr. 14, 2025.

The U.S. patent application “Back Side Power Delivery For Wafer-Scale Integration With An Isometric Grid Array With Compression Pins” Ser. No. 19/177,834, filed Apr. 14, 2025 is also a continuation-in-part of U.S. patent application “Back Side Power Delivery For Wafer-Scale Integration With Laser Assisted Bonding” Ser. No. 19/093,546, filed Mar. 28, 2025.

The U.S. patent application “Back Side Power Delivery For Wafer-Scale Integration With Laser Assisted Bonding” Ser. No. 19/093,546, filed Mar. 28, 2025, is also a continuation-in-part of U.S. patent application “Photonic Wafer-Scale Interposer With Tapered Waveguides” Ser. No. 19/079,851, filed Mar. 14, 2025.

The U.S. patent application “Photonic Wafer-Scale Interposer With Tapered Waveguides” Ser. No. 19/079,851, filed Mar. 14, 2025, is also a continuation-in-part of U.S. patent application “Back Side Power Delivery For Wafer-Scale Integration With An Isometric Grid Compression Plate” Ser. No. 19/056,456, filed Feb. 18, 2025, which claims the benefit of U.S. provisional patent applications “Chiplet-Based Optical Wafer-Scale Network Switch” Ser. No. 63/750,817, filed Jan. 29, 2025, and “Wafer-Scale Integration Power Delivery With An Isotropic Conductive Adhesive” Ser. No. 63/750,822, filed Jan. 29, 2025.

The U.S. patent application “Back Side Power Delivery For Wafer-Scale Integration With An Isometric Grid Compression Plate” Ser. No. 19/056,456, filed Feb. 18, 2025, is also a continuation-in-part of U.S. patent application “Back Side Power Delivery For Wafer-Scale Integration With Solderless Modular Power Substrates” Ser. No. 19/023,647, filed Jan. 16, 2025, which claims the benefit of U.S. provisional patent applications “Cooling for Wafer-Scale Integration With Back Side Power Coupling” Ser. No. 63/714,353, filed Oct. 31, 2024, and “Back Side Wafer-Scale Power Delivery With An Anisotropic Conductive Film” Ser. No. 63/720,216, filed Nov. 14, 2024.

The U.S. patent application “Back Side Power Delivery For Wafer-Scale Integration With Solderless Modular Power Substrates” Ser. No. 19/023,647, filed Jan. 16, 2025 is also a continuation-in-part of U.S. patent application “Wafer-Scale Integration With A Stiffening Isometric Grid Array” Ser. No. 18/978,188, filed Dec. 12, 2024, which claims the benefit of U.S. provisional patent applications “Cooling for Wafer-Scale Integration With Back Side Power Coupling” Ser. No. 63/714,353, filed Oct. 31, 2024, and “Back Side Wafer-Scale Power Delivery With An Anisotropic Conductive Film” Ser. No. 63/720,216, filed Nov. 14, 2024.

The U.S. patent application “Wafer-Scale Integration With A Stiffening Isometric Grid Array” Ser. No. 18/978,188, filed Dec. 12, 2024 is also a continuation-in-part of U.S. patent application “Cold Plate Cooling For Wafer-Scale Integration With Back Side Modular Power Delivery” Ser. No. 18/958,107, filed Nov. 25, 2024, which claims the benefit of U.S. provisional patent applications “Cooling for Wafer-Scale Integration With Back Side Power Coupling” Ser. No. 63/714,353, filed Oct. 31, 2024, and “Back Side Wafer-Scale Power Delivery With An Anisotropic Conductive Film” Ser. No. 63/720,216, filed Nov. 14, 2024.

The U.S. patent application “Cold Plate Cooling For Wafer-Scale Integration With Back Side Modular Power Delivery” Ser. No. 18/958,107, filed Nov. 25, 2024, is also a continuation-in-part of U.S. patent application “Back Side Wafer-Scale Integration With Modular Power Delivery” Ser. No. 18/940,944, filed Nov. 8, 2024, which claims the benefit of U.S. provisional patent application “Cooling for Wafer-Scale Integration With Back Side Power Coupling” Ser. No. 63/714,353, filed Oct. 31, 2024.

Each of the foregoing applications is hereby incorporated by reference in its entirety.

### FIELD OF ART

This application relates generally to sending data and more particularly to a photonic wafer-scale interposer with angled beam grating couplers.

### BACKGROUND

Communications between on-chip devices has evolved due to the need for faster, more efficient, and integrated communication systems to support ever-increasing computer capability. Early communication systems relied on discrete components-vacuum tubes, resistors, and capacitors-assembled into bulky circuits. These systems, used in telegraphs and early radios, were inefficient and limited in functionality. The invention of the transistor marked a turning point as a more reliable base for electronic components. However, the foundation for on-chip based communication was not truly laid until the later invention of the integrated circuit. Soon after, integrated circuits began to appear in communication systems, most notably in military and aerospace applications where basic analog circuits, such as amplifiers and oscillators, were used for radio frequency communication. Rapid advancements in chip processing and complexity followed, enabling more sophisticated communication functions.

The development of complementary metal-oxide-semiconductor (CM OS) technology revolutionized chip design. By offering lower power and higher circuit densities, a proliferation of communication applications was enabled. Chips began incorporating digital signal processing capabilities, allowing modulation and demodulation tasks to be performed on a single IC. Microprocessors soon followed, which enabled early modems and networked systems. Wireless communication chips soon followed suit as demand for mobile phones drove innovations in RF integrated circuits, combining analog and digital components. Soon, voice encoding, transmission, and reception were handled on a single chip. Standards, such as the Global System for Mobil Communication (GSM) further accelerated chip development, requiring integrated solutions for baseband and RF processing.

The Internet has been the largest growth driver for high speed communication chips. Ethernet controllers and modem ICs became commonplace, integrating complex protocols on a single chip. System-on-chip (SoC) designs emerged, combining microprocessors, memory, and communication interfaces. This integration reduced costs and power usage but also required new on-chip communications. Wireless standards continued to push communications within SoC designs, even while advances in optical lithography enabled smaller and smaller feature sizes, boosting performance and allowing more transistors to be added.

Modern SoCs integrate processor cores, specialized accelerators, security modules, multi-band RF transceivers, and so on. Chip communications must continue to advance to enable fast, high bandwidth data sharing between these units as well as other chips and SoCs.

### SUMMARY

The users of computers and other electronic devices demand ever faster performance from these electronic necessities. Further, the applications operated by the user further drive the necessity for new designs and architectures for the devices and the applications. Device features are also impelling technological and architectural improvements. Popular electronic devices now boast features including biometric authentication, increased resolution cameras, and three-dimensional audio. Whether the computers are vast, multisite server farms, or handheld devices, users always desire faster and more capable systems and devices than the current offerings. Thus, designers propose, design, and fabricate improved integrated circuits with ever-increasing processing performance, expanded data processing options, and “product differentiating” features. However, increased chip performance and added functionality such as AI processing force the addition of large, complex circuitry. To add new circuitry to the chips, designers employ two main design philosophies: increase the physical dimensions of the chip by making it larger or increase circuit density by reducing feature sizes. These techniques have so far been successful in meeting the never-ending customer demands for increased performance. As a result, microprocessors, graphics processors, machine learning accelerators, systems-on-chips (SoCs), and so on currently boast transistor counts into the tens of billions. Concomitant with increasing performance, the architectural improvements and added devices increase the power density of the chips, resulting in prodigious heat generation.

Disclosed techniques enable a photonic wafer-scale interposer with angled beam grating couplers. A photonic wafer-scale interposer (PWSI) is accessed. A front side of the PWSI is bonded to a plurality of chiplets. The plurality of chiplets includes at least one surface-emitting light source, a first chiplet, and a second chiplet. The PWSI includes a plurality of waveguides. Data is sent by a first chiplet to a first surface-emitting light source within the at least one surface-emitting light source. Light is emitted by the first surface-emitting light source. The light that was emitted is based on the data that was sent. The emitting includes angling the light, by an optical element (OE). The light that was angled from the first surface-emitting light source is coupled by a grating coupler within the PWSI to a first waveguide within the plurality of waveguides. The data that was sent is received by the second chiplet. The receiving is based on the light that was coupled to the first waveguide.

A method for sending data is disclosed comprising: accessing a photonic wafer-scale interposer (PWSI), wherein a front side of the PWSI is bonded to a plurality of chiplets, wherein the plurality of chiplets includes at least one surface-emitting light source, a first chiplet, and a second chiplet, and wherein the PWSI includes a plurality of waveguides; sending data, by the first chiplet, to a first surface-emitting light source within the at least one surface-emitting light source; emitting light, by the first surface-emitting light source, wherein the light that was emitted is based on the data that was sent, and wherein the emitting includes angling the light, by an optical element (OE); coupling, by a grating coupler within the PWSI, the light that was angled from the first surface-emitting light source, to a first waveguide within the plurality of waveguides; and receiving, by the second chiplet, the data that was sent, wherein the receiving is based on the light that was coupled to the first waveguide.

Various features, aspects, and advantages of various embodiments will become more apparent from the following further description.

### BRIEF DESCRIPTION OF THE DRAWINGS

The following detailed description of certain embodiments may be understood by reference to the following figures wherein:

FIG. 1 is a flow diagram for a photonic wafer-scale interposer with angled beam grating couplers.

FIG. 2 is a flow diagram for providing power.

FIG. 3 illustrates a flip-chip and interposer with flip-chips for wafer-scale integration.

FIG. 4 is a diagram of a modular power substrate.

FIG. 5 is a diagram of an isometric grid array.

FIG. 6 is a diagram of a waveguide.

FIG. 7 is a top view and a side view of a grating coupler.

FIG. 8 is a cross-section for a photonic wafer-scale interposer with angled beam grating couplers.

FIG. 9 is a cross-section of a photonic wafer-scale interposer with an angled beam grating coupler.

FIG. 10 is an apparatus for a photonic wafer-scale interposer with angled beam grating couplers.

FIG. 11 is a system diagram for a photonic wafer-scale interposer with tapered waveguides.

### DETAILED DESCRIPTION

Techniques for sending data using a photonic wafer-scale interposer with angled beam grating couplers are disclosed. The development of new, computationally intensive applications is driving demand for significant processing performance improvements. To meet these demands, vastly increased numbers of transistors have been added to a wide variety of chips such as chiplets and systems-on-chip (SOCs). The chiplets can include processors, memories, switching elements, and so on. SOCs can include modules or cores such as processors, memories, input/output (I/O) circuits, network switches, and other elements. The SOCs can be dimensionally large, possessing tens of billions of transistors. At the same time, feature sizes of elements within the SOCs continue to shrink. Keeping chip sizes roughly the same size while increasing the transistor count is generally good news, but new technologies that drive smaller transistors also impose new challenges for designers. These challenges include increased leakage currents, resulting in higher power consumption and increased heat dissipation for the chip. Leakage currents, in combination with the active power requirements, can drive extremely high-power densities for processors and other computing elements. Further, the wafers on which these large chips are fabricated are delicate. The wafers can fracture if the wafers are not properly handled and supported during fabrication, packing, deployment, etc.

One design objective that has been proposed to meet the processing requirements of compute intensive application is to design using wafer-scale integration, where an entire wafer is used for a single chip. However, because of physical defects distributed randomly across a wafer, circuitry fabricated on the defects will likely not perform as expected, if at all. Instead, the technique based on using an interposer has been developed. Here, circuits such as chiplets are bonded to the interposer. In effect, the goal of wafer-scale integration can be achieved by bonding functioning circuits across the entire interposer. While wafer-scale integration holds promise to deliver the performance enhancement necessary for today's workloads, challenges remain. For example, interconnections between many chips bonded to a wafer interposer can be challenging-both in the number of connections required and in bandwidth requirements for each connection. It can be necessary for a chip on one side of the interposer to communicate with another chip on the other side. Traditional wiring paths can be widened to reduce RC delays, but bandwidth can suffer for long paths since it is not feasible to drive a line the full length of a wafer in a typical processor cycle time. Other challenges also remain. A wafer interposer can be brittle and difficult to handle, especially with a plurality of chiplets and other elements bonded to a front side. Further, the coplanarity of the wafer interposer can vary, resulting in less-than-optimal electrical connections across the front side and back side of the wafer interposer. Grinding of the interposer, which can enable technologies such as through-silicon vias (TSV s), can thin the wafer interposer, making it still more difficult to handle without cracking. A further challenge is delivering power to the chips bonded to the interposer. A front-side power delivery scheme can make it difficult to deliver power in the center of the chips, thus making the system susceptible to voltage droop. Another complication is the difference in the thermal coefficient of expansion between a typical WSI stack-up, causing various elements to expand at different rates as temperatures rise due to operation. This can cause additional failures within a system. These issues present a substantial technical challenge for the handling, assembly, and operation of wafer interposers.

To address the technical challenges, while enabling highspeed data communications within the wafer-scale integration interposer described above, a photonic wafer-scale interposer with angled beam grating couplers is disclosed. A photonic wafer-scale interposer (PWSI) is accessed. A front side of the PWSI is bonded to a plurality of chiplets. The plurality of chiplets includes at least one surface-emitting light source, a first chiplet, and a second chiplet. The plurality of chiplets can include switching chiplets, I/O chiplets, and so on. The PWSI includes a plurality of waveguides, Data is sent by the first chiplet to a first surface-emitting light source within the at least one surface-emitting light source. The surface-emitting light source can include a vertical-cavity surface-emitting laser (VCSEL). Light is emitted by the first surface-emitting light source. The light that was emitted is based on the data that was sent. The sent data can include serial data. The emitting includes angling the light, by an optical element (OE). A grating coupler within the PWSI couples the light that was angled from the first surface-emitting light source to a first waveguide within the plurality of waveguides. The second chiplet receives the data that was sent. The receiving is based on the light that was coupled to the first waveguide.

The PWSI includes a plurality of waveguides. The waveguides can include tapered waveguides. A front side of the PWSI is bonded to at least two chiplets. The WSII includes a plurality of through-silicon vias (TSVs). The TSVs provide connectivity between a front side of the WSII and a back side of the WSII. The at least two chiplets are coupled. The coupling is based on one or more waveguides in the plurality of waveguides. The waveguides can be accessed using couplers. Data is sent, by a first chiplet within the at least two chiplets, to a second chiplet within the at least two chiplets. The chiplets can include switching chiplets, artificial intelligence (AI) accelerator chips, and so on. Data that is sent by the first chiplet can include digital data such as digital serial data. The digital data can be converted to optical data using a light source such as a surface-emitting light source. The second chiplet receives the data that was sent. A receiver associated with the second chiplet receives the data and provides digital data to the second chiplet.

A plurality of modular power substrates (MPSs) can be coupled to a back side of the PWSI. The coupling can be accomplished using one or more elastomer sheets. The coupling can include compressing the PWSI. The compressing can be based on mounting an isometric grid array (IGA) to a cold plate. The cold plate can remove a portion of excess heat generated by the plurality of chiplets. The mounting can be based on one or more spring-loaded fasteners, one or more clamps, and so on. These can be configured to provide a desired amount of compression. The compressing can maintain a coplanarity of the PWSI. The coupling the MPSs can couple each MPS within the plurality of MPSs to one or more chiplets within the plurality of chiplets. The MPSs can provide power to the one or more chiplets and other electronic elements such as surface-emitting light sources.

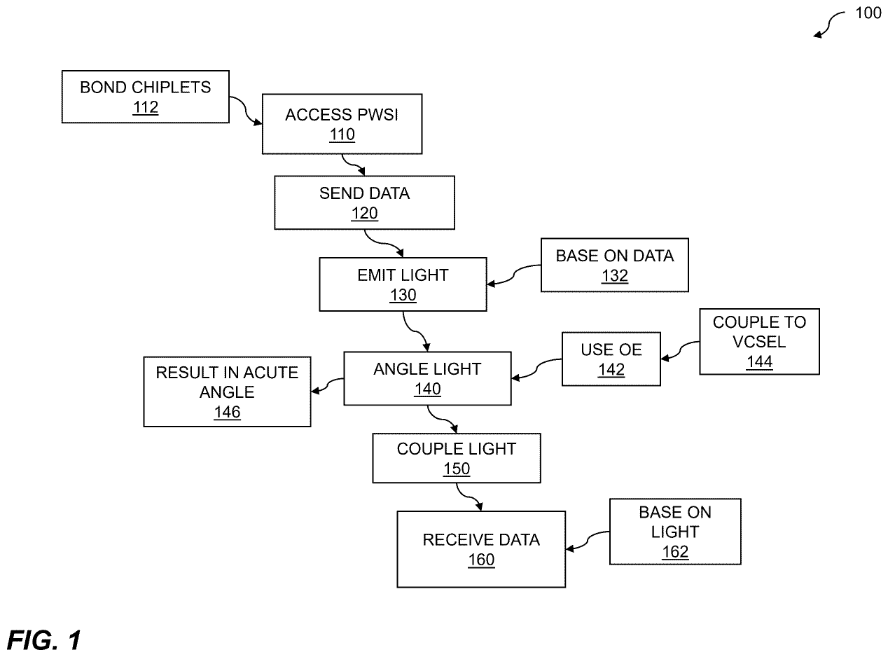

FIG. 1 is a flow diagram for a photonic wafer-scale interposer with angled beam grating couplers. The flow 100 includes accessing 110 a photonic wafer-scale interposer (PWSI). With wafer-scale integration, an entire wafer such as a silicon wafer could be used to fabricate one large circuit or system. In the flow 100, a front side of the PWSI is bonded to a plurality of chiplets 112. The chiplets can include processing chiplets, memory chiplets, I/O chiplets, and so on. The plurality of chiplets includes at least one surface-emitting light source, a first chiplet, and a second chiplet, and wherein the PWSI includes a plurality of waveguides. The wafer-scale integration system can be configured to perform complex processing tasks. In embodiments, the PWSI can include an optical wafer-scale AI accelerator, wherein one or more chiplets within the plurality of chiplets can include one or more artificial intelligence (AI) accelerators. The plurality of chiplets can further include a machine learning (ML) accelerator, a transformer, and so on. In other embodiments, the PWSI can include an optical wafer-scale network switch, wherein one or more chiplets within the plurality of chiplets can include one or more switching chiplets. The optical wafer-scale network switch can enable high-speed switching of data including large amounts of data. In embodiments, the plurality of chiplets includes one or more I/O chiplets. The I/O chiplets can include driver chiplets, interface chiplets, bus interface chiplets, and the like. The I/O chiplets can include chiplets that support industry standard communications protocols.

The waveguides can be built in a variety of technologies. In a usage example, a waveguide includes a silicon waveguide, fabricated on a silicon substrate, using a Silicon-on-Insulator fabrication technology. The waveguide can be used to send any type of data, such as AI data, communication packets, switch data requests and/or responses, and so on. As described previously, the chiplets can comprise AI accelerators, switching chiplets, processors, multicore processors, SoCs, ASICS, memory such as HBM, optical chips such as VCSELs, and so on. The chiplets can include chips designed for sending and receiving data, such as serial data. The serial data can comprise a SERDES format, Universal Chiplet Interconnect Express (U Cle) format, or another serialized data format. The data can include electrical data and/or optical data. The chiplets can include other functional, optical, etc. elements.

The flow 100 includes sending data 120, by the first chiplet, to a first surface-emitting light source within the at least one surface-emitting light source. The sending data can include sending digital data. The digital data can comprise point-to-point communications such as AMBA/AXI, serial communications such as PCI-Express (PCIe), or another suitable communications protocol. The digital data can be converted to optical data by a surface-emitting light source. In embodiments, the sending data is based on one or more metal layers within the PWSI. The PWSI can include metal layers, where the metal layers include wire or interconnect that is on or within the PWSI. The metal layers can be used to communicate between and among chiplets bonded to the front side of the PWSI. The metal layers can enable highspeed communication between chiplets, light sources, etc. because of their short lengths and their proximity to the chiplets. The surface-emitting light source can be based on other light-emitting techniques such as light-emitting diode (LED) techniques.

The flow 100 includes emitting light 130, by the first surface-emitting light source. The emitted light can be based on a wavelength of light. In a usage example, the wavelength of the emitted light can include 850 nm. In a second usage example, the wavelength of the emitted light can include 940 nm. The surface-emitting light source can be fabricated on, bonded to, or otherwise coupled to the PWSI. In embodiments, the first surface-emitting light source comprises a first vertical-cavity surface-emitting laser (VCSEL). The VCSEL can emit light in the near-infrared (NIR) range of wavelengths. The light emitted by the VCSEL can be modulated. In the flow 100, the light that was emitted is based on the data that was sent 132. The data that was sent can include digital data such as serial digital data. The serial digital data can be converted to optical data by the VCSEL.

In the flow 100, the emitting includes angling the light 140, by an optical element (OE). In order to enable coupling of the emitted light into a waveguide (discussed below), the emitted light can be angled. In the flow 100, the angling is accomplished by the OE. A variety of techniques can be used to accomplish the angling of the light by the OE. In embodiments, the OE can include a micro lens. The micro lens can be coupled to a light source such as a VCSEL, LED, laser diode, and so on. In other embodiments, the OE can include a Fresnel lens. A diffractive lens such as a Fresnel lens can have a lower profile than a traditional lens such as the microlens. In further embodiments, the OE comprises an asymmetric non-focusing optical device. A non-focusing optical device can be used to guide, reflect, or distribute light. A non-focusing optical device can guide the emitted light into a waveguide. A surface-emitting light source such as the VCSEL discussed previously can emit light that is substantially perpendicular to a front service of the PWSI. In embodiments, the OE 142 is coupled to the first VCSEL 144. The coupling the OE can be accomplished by fabricating the OE with the VCSEL, bonding the OE to the VCSEL, adhering the OE to the VCSEL, and so on. In some embodiments, the angling results in an acute angle 146 to the grating coupler. The acute angle to the grating coupler can enhance coupling light by the grating coupler to a waveguide.

The flow 100 includes coupling 150, by a grating coupler within the PWSI, the light that was angled from the first surface-emitting light source, to a first waveguide within the plurality of waveguides. The grating coupler can receive the angled light. The angle associated with the light can be an acute angle relative to the grating coupler. In a usage example, the angled light can impinge on the grating coupler at an angle of 45 degrees. The grating coupler can be “tuned” or configured to a wavelength of light. The configuring the grating coupler can enable a substantial portion of the emitted light to be coupled to a waveguide. The waveguide can be used to send data as optical data between a first chiplet and a second chiplet, where the first chiplet and the second chiplet are bonded to a front side of the PWSI. The optical data that is sent can be converted to optical data from digital data, such as serial digital data, by a surface-emitting light source. The optical data can be detected using a device such as a photodiode, a photo Darlington transistor, and so on.

The flow 100 includes receiving 160, by the second chiplet, the data that was sent. The data that is received can include optical data such as serial optical data. The optical data can be encoded. In embodiments, the receiving is based on the light 162 that was coupled to the first waveguide. The receiving the data can be accomplished using a second coupler. The second coupler can include an optical coupler such as a beam grating coupler. The second coupler can include an electro-optic device such as a photodiode, a photo Darlington transistor, and the like. The receiving the data can include using the second optical coupler to couple the optical information from the first waveguide to an optical receiver. The optical receiver can include an element within the second chiplet, an element coupled to the second chiplet, and the like. The receiver can include an electro-optical receiver. The photodiode, the photo Darlington transistor, etc. can convert the serial optical data to serial electrical data. When present, the optical receiver can transfer the data to the second chiplet. The data can be sent as serial data, parallel data (eg., as bytes, words, etc.) by the optical receiver to the second chiplet. The sending can be accomplished using interconnect associated with one or more layers of interconnect on and within the PWSI.

Various steps in the flow 100 may be changed in order, repeated, omitted, or the like without departing from the disclosed concepts. Various embodiments of the flow 100 can be included in a computer program product embodied in a non-transitory computer readable medium that includes code executable by one or more processors. Various embodiments of the flow 100 can be included in an apparatus for power delivery or system that is configured to deliver power.

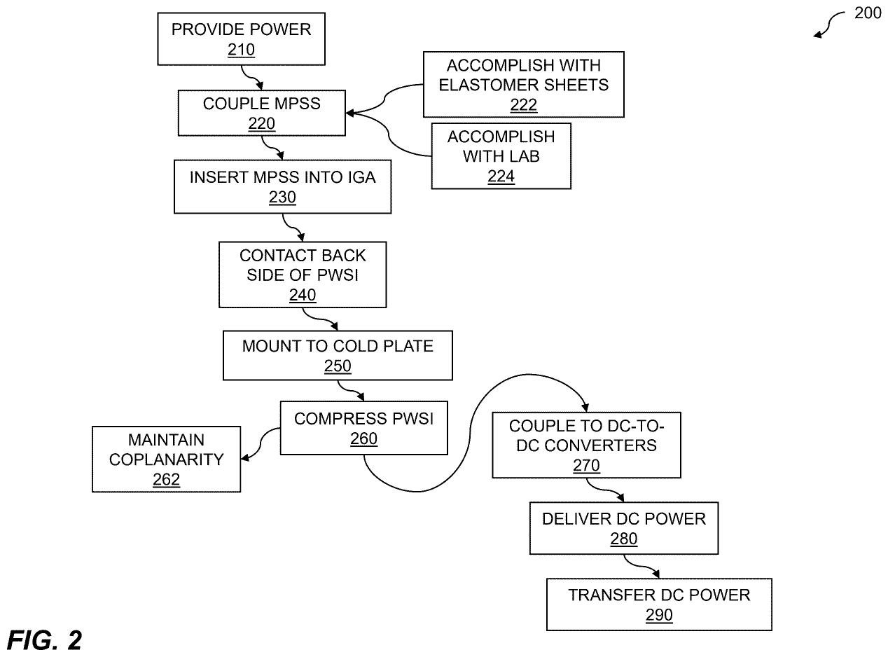

FIG. 2 is a flow diagram for providing power. Integrated circuits or chips such as chiplets, surface-emitting light sources, functional chips, and so on can be bonded to a photonic wafer-scale interposer (PWSI). The use of the PWSI supports wafer-scale integration (WSI), which is particularly useful to supporting the processing requirements of computationally intensive applications such as artificial intelligence (AI) acceleration, machine learning applications, and the like. The chiplets that can enable high-speed data transfer using angled beam grating couplers and waveguides, and the functional chips that execute the computationally intensive applications, require significant amounts of power during operation. The power, which includes DC power, must be provided chiplets, light sources, and functional chips. The power can be provided using modular power delivery techniques. At least a portion of the generated heat can be transferred to a coolant that can be sent to a cold plate. Thus, providing DC power enables a photonic wafer-scale interposer with angled beam grating couplers. The PWSI can include a 300 mm wafer, a 200 mm wafer, or a wafer of another size.

The flow 200 includes providing power 210 to a plurality of chiplets, wherein the providing is based on a back side of the PWSI, and wherein the PWSI includes a plurality of through-silicon vias (TSVs). The providing power can include providing DC power. The chiplets, surface-emitting light sources, functional chips, etc. require power such as DC power to operate. The power can be provided by attaching one or more power modules (described below) to a back side of the PWSI. In order for the power to reach the chiplets, light sources, and other elements, the power can be provided from the back side of the PWSI to the front side of the PWSI using the plurality of TSV s.

The flow 200 includes coupling 220, to the back side of the PWSI, a plurality of modular power substrates (MPSs). The coupling can be accomplished using a variety of techniques. In some embodiments, the coupling is accomplished via one or more elastomer sheets 222. The elastomer sheets can include conducting filaments. The conducting filaments can provide a conduction path from a front side of an elastomer sheet to a back side of the elastomer sheet. In other embodiments, the coupling is accomplished via laser-assisted bonding (LAB) 224. Using LAB, solder balls, such as microbumps and controlled collapse chip connection bumps (C4s), can be melted using a laser. The melting the solder balls using a laser tightly concentrates heating of the solder balls while leaving previous fabrication steps, such as diffusion, soldering, and so on, unharmed.

The flow 200 includes inserting 230 each MPS within the plurality of MPSs that was coupled into an isometric grid array (IGA), wherein the IGA includes a plurality of open recesses. The open recesses can enable coupling a plurality of modular power substrates (MPSs) to the back side of the PWSI. The sizes of the open recesses can be chosen to accommodate the MPSs and a lateral displacement of the MPSs that can result from heating of the MPSs during operation. The IGA can include square open recesses or further shapes appropriate to a form factor of the MPSs. The further shapes can include rectangles, circles, ovals, a honeycomb, etc. Recall that the MPSs can be based on a form factor, where each MPS can be based on a form factor mirroring one or more corresponding functional chips. The form factor associated with the MPSs can also be applied to the IGA. Each open recess within the plurality of open recesses within the IGA can match a form factor of a corresponding MPS in the plurality of MPSs.

In embodiments, the plurality of open recesses comprises a grid, wherein the IGA contacts the back side of the PWSI 240 between each MPS within the plurality of MPSs that were bonded. Recall that the MPSs are coupled to the back side of the PWSI. The IGA can contact the back side of the PWSI between each MPS in the plurality of MPSs. In a usage example, each of the open recesses within the IGA can be “filled” with an MPS coupled to the back side of the PWSI. If fewer than a full complement of MPSs has been coupled to the back side of the PWSI, then one or more of the open recesses within the IGA can remain open. The IGA can stiffen the PWSI as discussed and can provide other benefits to the PWSI. Note that the IGA can maintain a coplanarity of the PWSI. The coplanarity of the PWSI can counteract sagging or warping of the PWSI due to the weight of bonded and coupled elements, and any thermal expansion of elements such as functional chips and MPSs that are bonded to or coupled to the PWSI.

The flow 200 includes mounting the IGA to a cold plate 250, wherein the cold plate contacts the plurality of chiplets bonded to the front side of the PWSI. Thus, the IGA that contacts the back side of the PWSI, and the cold plate that contacts the chiplets bonded to the front side of the PWSI, can “sandwich” the PWSI. The sandwiching of the PWSI can support the PWSI. Further, the cold plate can remove at least a portion of the excess heat generated by the chiplets. The IGA can remove a portion of the heat generated by the MPSs. The mounting the IGA to the cold plate can be accomplished using a variety of techniques. In embodiments, the mounting is based on one or more spring-loaded fasteners. The spring-loaded fasteners can hold the IGA and the cold plate together based on a compression force. The mounting the IGA to the cold plate can also be accomplished using screws, bolts, clips, and so on. In other embodiments, the mounting is based on one or more clamps. The one or more clamps can be used to apply a substantial compression force, where the compression force can enable reliable coupling of MPSs to the PWSI, can maintain a coplanarity of the PWSI, and so on. The compression force, especially when elastomer sheets are used to couple the MPSs to the PWSI, can be increased through the use of one or more compression plates.

The flow 200 includes compressing the PWSI 260, wherein the compressing is based on the mounting, and wherein the compressing maintains a coplanarity 262 of the PWSI. The compressing can be accomplished by the IGA mounted to the cold plate. The compressing can accomplish coupling the plurality of MPSs to the PWSI via one or more elastomer sheets. Discussed throughout, the elastomer sheets can include conducting filaments, where the conducting filaments can enable an electrical connection between contacts associated with the MPSs and TSV, wiring, and so on associated with the PWSI. A modular power substrate can include one or more electrical elements, connectors, and so on. The coupling can be based on one or more controlled collapse chip connection bumps (C4s). In the flow 200, the compressing maintains a coplanarity 262. Recall that in addition to the IGA compressing the PWSI, the IGA can further enable stiffening of the PWSI, MPSs, and so on. The stiffening can enable planar compression of the MPSs, and thus planar compression of conductive connecting materials, such as elastomer sheets, used to couple the MPSs to the PWSI.

The flow 200 includes coupling the plurality of MPSs to a plurality of DC-to-DC power converters 270. The coupling can be accomplished using plug-and-socket connectors, terminals, cables, and so on. In embodiments, the plurality of DC-to-DC power converters comprises a unified control board (UCB), wherein the coupling is based on a plurality of sockets. In a usage example, the coupling an MPS to the UCB can be accomplished using a DC power connector and a plurality of rigid-flex strips. The coupling can be based on a high voltage socket. The UCB can include one or more digital controller chips to control the DC-to-DC power converters. The digital controller chips can comprise a processor, a multiprocessor, a microcontroller, and so on. The digital controller chip can control the DC-to-DC power converters.

The flow 200 includes delivering DC power 280, by the UCB, to the plurality of chiplets, wherein the delivering is based on the plurality of DC-to-DC power converters, the plurality of MPSs, and the plurality of TSVs, and wherein the delivering includes a first voltage conversion. The delivering DC power can include delivering DC power to a subset of MPSs. The delivering DC power can be accomplished by matching one or more DC-to-DC converters to one or more MPSs. Interconnection between the DC-to-DC converters matched with one or more respective MPSs can be accomplished using interconnect associated with the UCB. The DC power that is delivered can include a range for the DC voltage. The range of DC voltage can include a percentage of a target voltage, an allowable operating range of DC voltage, and the like. In a usage example, the voltage range can include 48 volts to 54 volts, inclusive. The delivering can include a first voltage conversion.

The flow 200 further includes transferring the DC power 290 that was delivered, by the plurality of MPSs, to the plurality of chiplets, wherein the transferring includes a second voltage conversion. The plurality of chiplets can obtain the directed power using interconnect, contacts, and so on. The chiplets and other electronic elements can also use interconnect and contacts to receive and send data, instructions, control signals, etc. The second voltage conversion can be accomplished using one or more converters such as DC-to-DC converters associated with the MPSs. The second voltage conversion can produce a voltage that can be used directly to operate one or more chiplets. The second voltage conversion can attain a voltage less than the voltage resulting from the first voltage conversion. The second voltage conversion can result in a voltage less than a threshold. The threshold can include a target voltage, an operating voltage, and so on. In a usage example, the threshold is 1 volt. The transferring is based on the plurality of TSV s. The transferring can include transferring DC power, receiving and sending data, sending and receiving functional chip instructions and control signals, etc.

Various steps in the flow 200 may be changed in order, repeated, omitted, or the like without departing from the disclosed concepts. Various embodiments of the flow 200 can be included in a computer program product embodied in a non-transitory computer readable medium that includes code executable by one or more processors. Various embodiments of the flow 200 can be included in an apparatus for power delivery or system that is configured to deliver power.

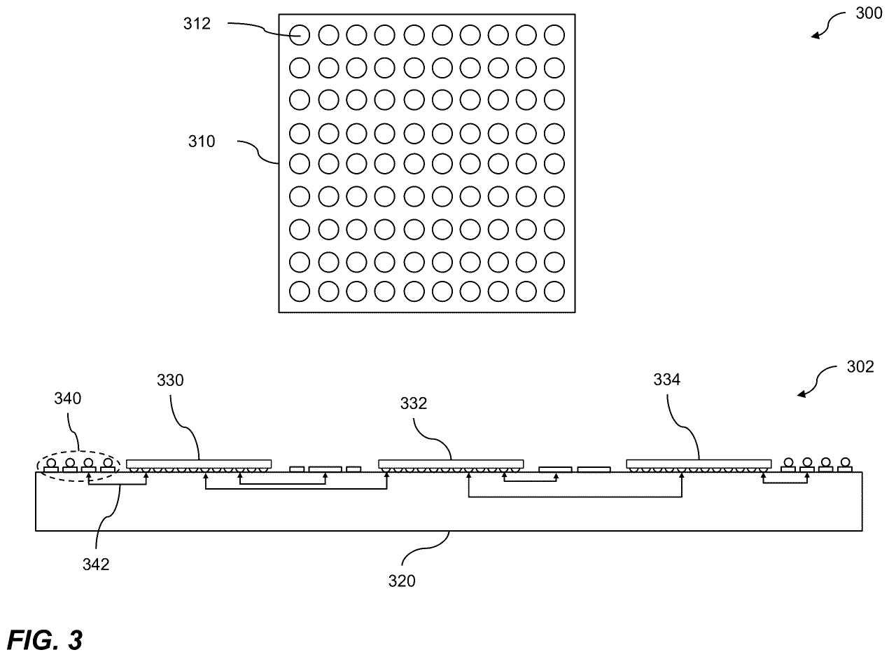

FIG. 3 illustrates a flip-chip and interposer with flip-chips for wafer-scale integration. One technique that can be used to approach the benefits of wafer-scale integration is to attach more than one chip to a common substrate or interposer. The interposer, as here, can include a photonic interposer. The substrate can include a wafer, a carrier, a circuit board, and so on. To accomplish such a technique, all interconnections to a circuit or chip, including data connections, control and signal connections, power connections, and so on, can be made at the top layer of the chip. The connections at the top of the chip replace the traditional placement of pads at the periphery of the chip. To connect the top connections of the chip to the interposer, solder balls are placed on the top connections and the chip is inverted or “flipped.” The solder balls, when melted, can connect the top connections of the chip to corresponding connections or pads on the interposer. Further chips can be similarly flipped and connected to additional corresponding connections on the interposer. One challenge to the flip-chip technique is providing power to the chips. The power can be provided using back side power delivery. Another challenge to the flip-chip technique is providing high-speed communications for sending data between and among chips bonded to the interposer. The sending data can be enabled using a photonic wafer-scale interposer with angled beam grating couplers. A further challenge to the flip-chip technique is that the aggregate weight of the flipped chips can be sufficient to pose a risk to the delicate wafer or interposer. The wafer can be stiffened in order to protect it from the weight of the flipped chips and other elements. The wafer can further be stiffened using one or more reinforcement structures. The plurality of reinforcement structures can enable planar compression of each elastomer sheet within a plurality of elastomer sheets. The elastomer sheets enable attachment of elements such as a plurality of MPSs to a back side of a photonic wafer-scale interposer (PWSI). The PWSI can include tapered waveguides.

The FIG. 300 includes an example flip-chip. Discussed previously, the flip-chip 310 differs from a traditional chip in that the connections to the flip-chip are made at the top of the chip rather than to pads located at the periphery of the chip. A top view of a flip-chip is shown. The top can include pads that can be connected to corresponding pads on a multi-chip module, a circuit board, an interposer, and so on. An example contact or pad 312 is shown. Multiple pads can be distributed across the top of the flip-chip. The pads can be oriented to correspond with receiving pads on the interposer. An array of pads is shown. In a usage example, a subset of pads can be required to connect the flip-chip to the interposer. Thus, required pads are present at the top of the flip-chip, while the unused pads can be omitted from the top of the flip-chip.

The illustration 302 shows an example interposer. As discussed previously, the interposer 320 can include a wafer, a carrier, a circuit board, and so on. One or more flip-chips can be bonded to the interposer. In the figure, the flip-chips can include a first flip-chip 330, a second flip-chip 332, a third flip-chip 334, and so on. While three flip-chips are shown, other numbers of flip-chips can be bonded to the interposer. In a usage example, the flip-chips can be bonded to the interposer in a grid pattern. In addition to serving as a placement location for the flip-chips, the interposer can provide interconnect. The interconnect can be used to provide signals such as control signals, data, and so on to the flip-chips. The interconnect can further provide power to the flip-chips. Depending on the interposer used to receive the flip-chips, the interposer can include one or more layers of interconnect. The interconnect can include interconnect at a top surface of the interposer such as top surface interconnect 340. The interposer can further include additional layers of interconnect. The additional layers of interconnect can be fabricated on the interposer. The additional layers of interconnect can be isolated from each other using an insulating layer between the conducting interconnect layers. An example “lower layer” connection 342 is shown.

The use of flip-chips bonded to an interposer can enable multichip module (MCM) techniques. A multichip module can refer to a substrate, carrier, circuit board, interposer, etc. onto which multiple ICs can be placed. The multiple ICs can be bonded to the interposer, and the multiple ICs can be wired together using interconnect provided by the interposer. The interconnect associated with the interposer can provide power, control signals, and data between and among the ICs that are bonded to the interposer. The power can be provided using modular power techniques. Depending on the particular type of MCM, the interposer can further include discrete components such as discrete resistors, discrete capacitors, discrete inductors, discrete diodes, etc. A principal advantage of using MCM s is that multiple electronic components can be enclosed in a single “chip,” thereby improving modularity of a system design. Also, the use of MCM s can improve IC yields over ICs produced using monolithic IC design methodologies.

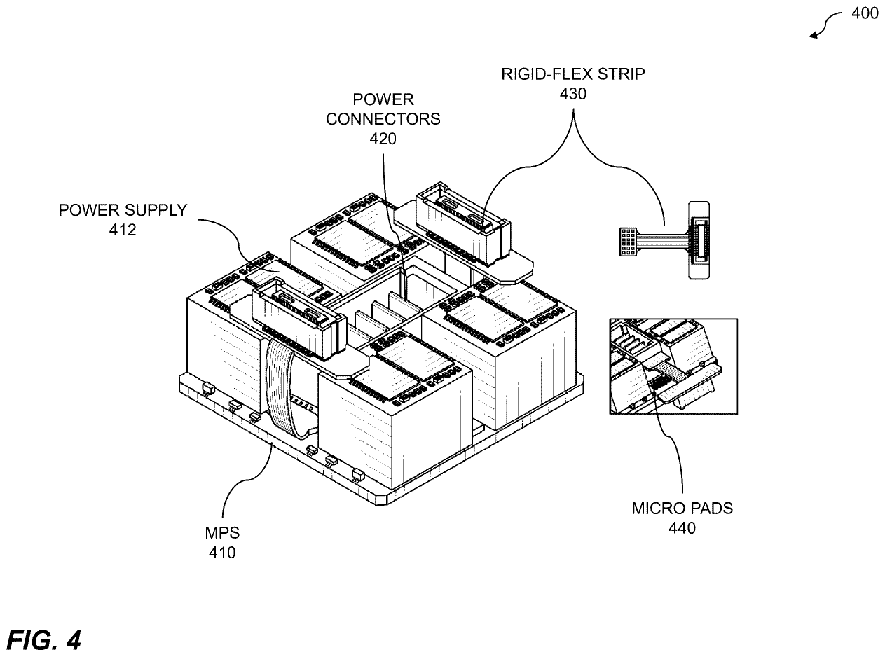

FIG. 4 is a diagram of a modular power substrate. Chiplets, including integrated circuits such as processor circuits, require power in order to operate. When a significant number of circuits or chiplets is obtained to achieve an objective such as a processing objective, the power requirements for the many chiplets and other elements become substantial, and the requirements for providing the power become more stringent. The more stringent power requirements can result because the aggregate power delivery to the chiplets can include tens, hundreds, or more amperes. The elements can include a surface-emitting light source such as a light-emitting diode (LED), a laser emitting diode, a vertical-cavity surface-emitting laser (VCSEL), and so on. Further, the many circuits to which the power is provided can generate copious heat (eg., thermal dissipation). The heat generated by the various elements of a system such as power supplies, chiplets, control circuits, and so on causes the elements to expand. Since the elements comprise different materials, coefficients of expansion of the elements can differ. To counter the potentially disastrous effects such as fracture resulting from differing coefficients of expansion (COEs), power supplies that can be used to power one or more chiplets can be arranged on one or more modular power substrates (MPSs). The MPSs can enable lateral displacement between other elements that expand and contract, minimizing potential material strain. The MPSs can be coupled to a substrate such as a photonic wafer-scale interposer (PWSI). The coupling can be accomplished via one or more elastomer sheets, laser-assisted bonding (LAB), and so on. The MPSs support a photonic wafer-scale interposer with angled beam grating couplers.

A wafer-scale integration interposer (WSII) is accessed. A front side of the WSII is bonded to a plurality of chiplets. The plurality of chiplets includes at least one surface-emitting light source, a first chiplet, and a second chiplet, and wherein the PWSI includes a plurality of waveguides. Data is sent, by the first chiplet, to a first surface-emitting light source within the at least one surface-emitting light source. Light is emitted, by the first surface-emitting light source. The light that was emitted is based on the data that was sent. The emitting includes angling the light, by an optical element (OE). A grating coupler within the PWSI couples the light that was angled from the first surface-emitting light source to a first waveguide within the plurality of waveguides. The second chiplet receives the data that was sent. The receiving is based on the light that was coupled to the first waveguide.

The diagram 400 shows a modular power substrate (MPS). Elements such as one or more power supplies, connectors, rigid-flex strips, etc. can be mounted to an MPS 410. The number of elements that can be bonded to the MPS can be based on the size, shape, and so on of the MPS. A plurality of MPSs can be used to deliver power to a plurality of chiplets. The MPSs can be based on a variety of substrate materials. In a usage example, one or more MPSs within the plurality of MPSs can include an organic substrate. An organic substrate can be based on one or more organic materials such as organic materials used to manufacture printed circuit boards. The organic substrate materials can include paper cores impregnated with phenolic resin; woven or unwoven glass cloth impregnated with epoxy or cyanate ester among others; natural fibers; etc. In a further usage example, one or more MPSs within the plurality of MPSs can include an inorganic substrate. An inorganic substrate can be based on a silicon glass with a coefficient of expansion similar to the WSII, etc.

An MPS can include a form factor. Recall that a plurality of chiplets can be bonded to a front side of a wafer-scale integration interposer (WSII). The WSII can include a photonic wafer-scale interposer (PWSI). A plurality of MPSs can be based on a form factor mirroring one or more corresponding chiplets, within the plurality of chiplets, on the front side of the PWSI. The plurality of MPSs is coupled to the plurality of chiplets. The MPSs can be electrically coupled to a unified control board (UCB) and to the back side of the WSII. The coupling of the MPSs to the PWSI can be accomplished via elastomer sheets, laser-assisted bonding (LA B), or another technique. Thus, the MPSs can be situated between the UCB and the PWSI. As described above, the PWSI and the UCB can have different coefficients of thermal expansion leading to different lateral movements. These lateral movements can be sufficient to crack connections and/or introduce warpage into components which can lead to connection failures such as disconnected connectors, cracked C4s, damage due to physical strain, etc. The modularity of the MPSs can provide a flexible power delivery system to the chiplets which can accommodate different movements of the PWSI and UCB due to thermal expansion. For example, an MPS at one side of the WSII can be decoupled from an MPS on the other side of the PWSI, thus accommodating various movements across the WSII and UCB.

A power supply 412 can be coupled to the MPS. In the figure, three additional power supplies are shown coupled to the MPS. The number of power supplies coupled to the MPS can be based on the dimensions of the MPS, the dimensions of the power supplies, a voltage or current required by the chiplets, coefficients of expansion, heat dissipation, etc. The power supplies can be stacked. The MPS can include one or more power connectors 420. The power connectors can fit with a high voltage socket, a high-power socket, etc. from the UCB. The power connectors can include one or more of positive terminals, negative terminals, common terminals, and so on. The high voltage socket can accommodate lateral movement due to thermal expansion. The MPS can include one or more rigid-flex strips 430. The one or more rigid-flex strips can be used to connect an MPS to the UCB. The connection can include control signals, power delivery, and so on. The rigid-flex strips can provide further protection from differing rates of thermal expansion between the WSII and the UCB, through the use of a flexible connector. The rigid flex strips can carry control information from the UCB to the MPS and can control the flow of DC power to the chiplets. The MPS can include one or more micro pads 440. The micro pads can include a ball grid array (BGA). The micro pads can enable bonding of the MPS to the WSII. The bonding can be accomplished using laser-assisted bonding. A laser can be used to reflow a single C4 connection, an entire IGA, and so on.

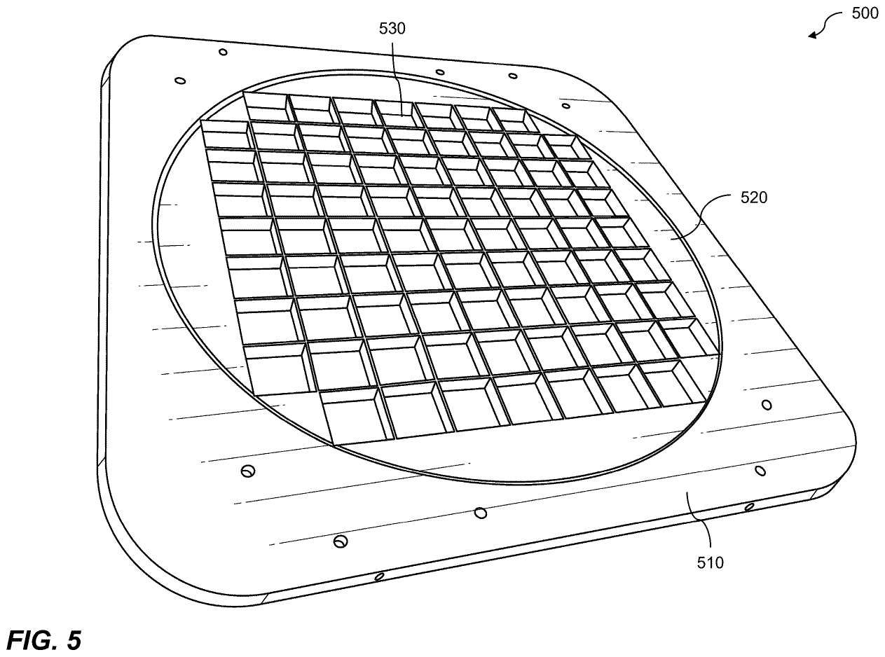

FIG. 5 is a diagram for an isometric grid array. The isometric grid array (IGA) can provide stiffening to a photonic wafer-scale interposer (PWSI). The PWSI can include a plurality of functional chips that can be bonded to a front side of the PWSI. A plurality of modular power substrates (MPSs) can be coupled to a back side of the PWSI. The coupling can be accomplished using one or more elastomer sheets, laser-assisted bonding (LA B), and so on. Each MPS within the plurality of MPSs can be inserted into an isometric grid array (IGA), where the IGA includes a plurality of open recesses. The attaching the MPSs to the back side of the PWSI is accomplished through a plurality of open recesses within the IGA. The plurality of open recesses comprises a grid. The IGA contacts the back side of the PWSI between each MPS within the plurality of MPSs that were bonded. The recesses within the IGA can accommodate lateral displacement of the MPSs due to thermal expansion of the MPSs. The walls of the open recesses within the MPSs can be sufficiently thin to minimize consumption of PWSI real estate by the IGA. The walls of the IGA can further be strong enough to support and stiffen the PWSI, thereby substantially reducing the risk of fracturing the PWSI. The fracturing of the PWSI can result from the thinness to which the PWSI was ground, polished, and so on in order to enhance fabrication of through silicon vias (TSV s) associated with the PWSI. The cracking or breaking can also result from the weight of the functional chips and the MPSs. The TSVs enable communication between the functional chips and the MPSs. The stiffening isometric grid array enables wafer-scale integration. The wafer-scale integration is enabled by a photonic wafer-scale interposer with angled beam grating couplers.

The FIG. 500 shows an isometric grid array (IGA) 510. The IGA can include a variety of materials such as various alloys of steel, aluminum, and so on. In a usage example, the IGA can comprise copper. The IGA can include a recess such as a circular recess 520. The recess 520 can include a variety of sizes, where the sizes can correspond to a size of a wafer. The wafer can include a 300 mm wafer, a 200 mm wafer, and the like. The recess can accommodate the PWSI. The IGA can further include open recesses such as open recess 530. The further open recesses can enable attaching a plurality of modular power substrates (MPSs) to the back side of the PWSI. The sizes of the open recesses can be chosen to accommodate the MPSs and a lateral displacement of the MPSs that can result from heating of the MPSs during operation. In embodiments, the IGA comprises a grid. The IGA grid can include square open recesses as shown, or further shapes appropriate to a form factor of the MPSs. The further shapes can include rectangles, circles, ovals, a honeycomb, etc. Recall that the MPSs can be based on a form factor. In embodiments, each MPS within the plurality of MPSs is based on a form factor mirroring one or more corresponding functional chips, within the plurality of functional chips, on the front side of the PWSI. The form factor associated with the MPSs can also be applied to the IGA. In embodiments, each open recess within the plurality of open recesses within the IGA matches a form factor of a corresponding MPS in the plurality of MPSs. Recall that the MPSs are coupled to the back side of the PWSI through the plurality of open recesses within the IGA. In embodiments, the IGA contacts the back side of the PWSI between each MPS in the plurality of MPSs. In a usage example, each of the open recesses within the IGA can be “filled” with an MPS coupled to the back side of the PWSI. If fewer than a full complement of MPSs has been coupled to the back side of the PWSI, then one or more of the open recesses within the IGA can remain open. The IGA can stiffen the PWSI as discussed and can provide other benefits to the PWSI. In embodiments, the IGA maintains a coplanarity of the PWSI. The coplanarity of the PWSI can counteract sagging or warping of the PWSI due to the weight of bonded and coupled elements, and any thermal expansion of elements such as functional chips and MPSs that are bonded to or coupled to the PWSI.

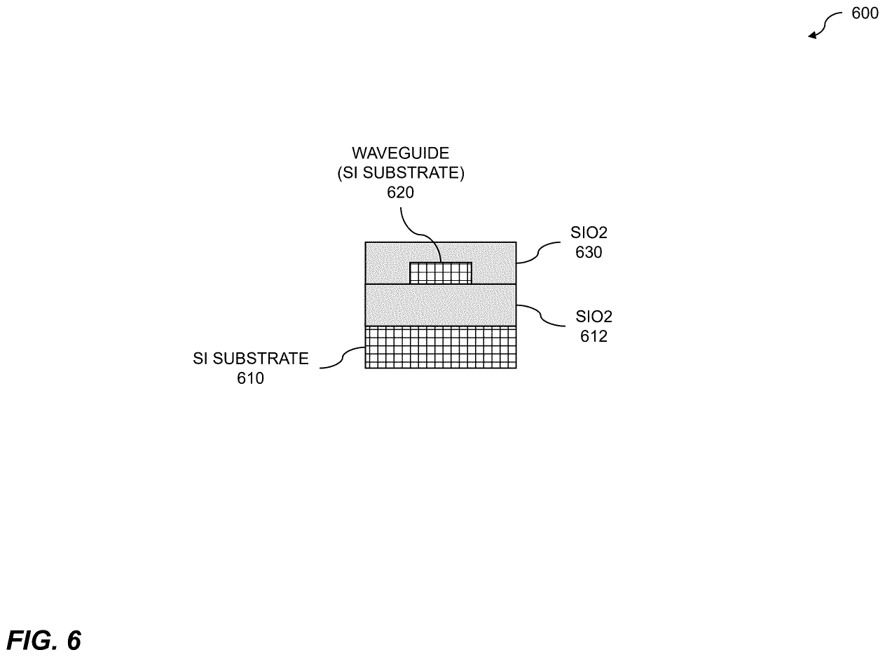

FIG. 6 is a diagram of a waveguide. A cross-section of a waveguide is shown. The waveguide can be fabricated in a technology such as a Silicon-on-Insulator (SOI) technology. A waveguide can be used to transfer a signal such as an optical signal between two elements. The elements can include switching chiplets, AI accelerator chiplets, etc. The chiplets can be associated with a switch such as a data switch, an AI accelerator, and so on. The waveguide can be fabricated within a monolithic wafer which includes one or more functional chips. The waveguide can be fabricated within a photonic wafer-scale interposer (PWSI), where the PWSI can be based on a wafer such as a silicon wafer, a glass wafer, and so on. The wafer can be used as a substrate for the PWSI. A plurality of waveguides can be fabricated within the PWSI in order to enable high speed, high bandwidth communications between chiplets. The communication between chiplets can include chiplets separated by a long distance on the PWSI. The waveguides can be tapered. The chiplets can be associated with a switch such as a network switch. The plurality of waveguides enables a photonic wafer-scale interposer with angled beam grating couplers.

The cross-section of an example waveguide fabricated in a Silicon-on-Insulator (SOI) technology is shown 600. A silicon substrate 610 is obtained. The silicon substrate can include a silicon wafer, where the silicon wafer can include a 200 mm silicon wafer, a 300 mm silicon wafer, and so on. A silicon dioxide (insulator) layer 612 can be grown, deposited, or otherwise formed on the silicon wafer. One or more waveguides, such as waveguide 620, can be formed on the insulator layer 612. Another insulator layer 630 can be placed over the one or more waveguides. The insulator layer can be planarized in order to enable fabrication of further elements. The waveguide can conduct light in order to establish optical communications between an optical source and an optical receiver within the PWSI.

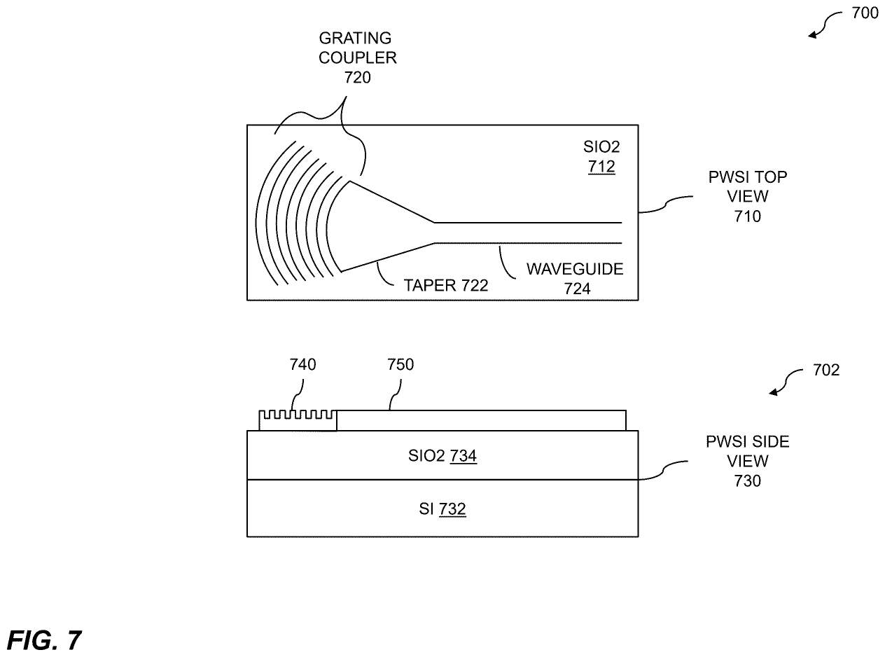

FIG. 7 is a top view and a side view of a grating coupler. Described previously and throughout, light that is emitted at an angle by a surface-emitting light source can be coupled to a waveguide using a grating coupler. The grating coupler can be “tuned” to a wavelength of light, such as 850 nm, to enable a substantial portion of the emitted light to be coupled to a waveguide. The waveguide can be one of a plurality of waveguides within a photonic wafer-scale interposer (PWSI). The waveguide can be used to send data as optical data between a first chiplet and second chiplet, where the first chiplet and the second chiplet can be bonded to a front side of the PWSI. The optical data that is sent can be converted from digital data, such as serial digital data, by a surface-emitting light source. The optical data can be detected using a device such as a photodiode, a photo Darlington, and so on. The grating coupler enables sending data using a photonic wafer-scale interposer.

A top view of a grating coupler 700 is shown. The grating coupler can be formed within a photonic wafer-scale interposer (PWSI) 710. The PWSI can include an insulation layer such as an SiO2 insulation layer 712. A grating coupler 720 can be formed on the SiO2 layer. The grating coupler can include a periodic structure as shown. The periodic structure can “focus” light directed at the grating coupler toward a taper 722. The taper can transfer light into a waveguide 724. The taper can be an adiabatic taper. The grating coupler can be based on diffraction. The grating coupler can enable a substantial portion of light directed toward the grating coupler to be directed into the waveguide. Further, a side view of the grating coupler formed on a PWSI 730 is shown 702. The PWSI can include a silicon (Si) wafer 732. An oxide layer (SiO2) 734 can be formed on the Si wafer. In turn, a grating coupler 740 can be formed on the oxide layer. The grating coupler can receive light at an angle from a first light source (not shown). In embodiments, the first surface-emitting light source can include a first vertical-cavity surface-emitting laser (VCSEL). Light from the VCSEL can be angled using an optical element (OE) (not shown). The OE can include a micro lens, a Fresnel lens, an asymmetric non-focusing optical device, etc. The OE can couple a portion of the emitted light that can be angled toward the grating coupler into a waveguide. In the FIG. 702, the waveguide can include waveguide 750.

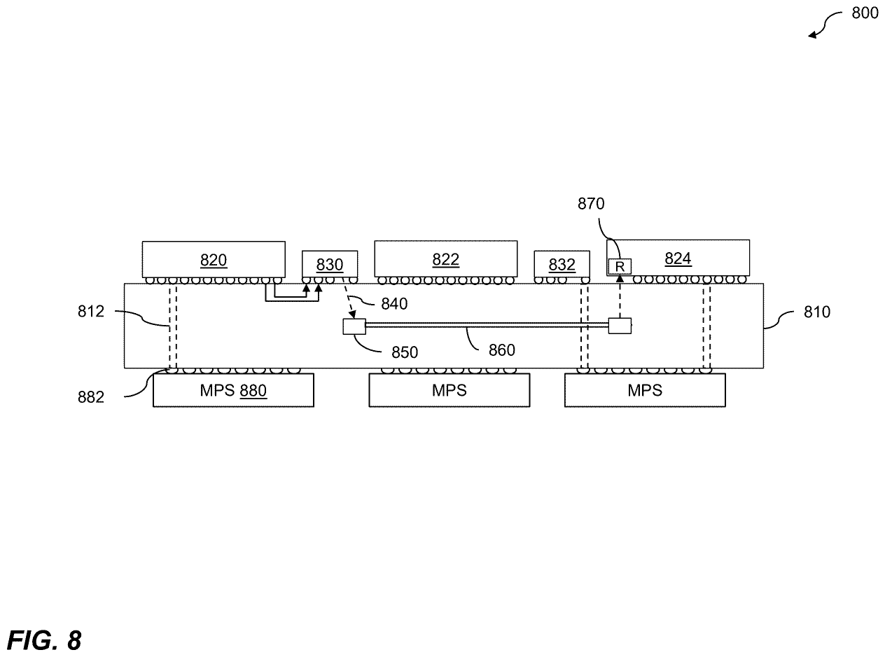

FIG. 8 is a cross-section for a photonic wafer-scale interposer (PWSI) with angled beam grating couplers. In order to improve interconnection bandwidth and/or speed, chiplets, such as switching chiplets, AI chiplets, surface-emitting light sources, and so on, can be bonded to a front side of a photonic-scale integration interposer (PWSI). The PWSI shown in cross-section 800 includes photonic elements. The PWSI includes a plurality of waveguides. A waveguide within the PWSI can enable coupling between any number of chiplets bonded to the PWSI. The waveguides can be used to transfer data between chiplets as optical signals. Coupling between the chiplets and the waveguides is accomplished by one or more surface-emitting light sources. In embodiments, the surface-emitting light source comprises a vertical-cavity surface-emitting laser (VCSEL). Data from a chiplet can be sent to a VCSEL. The VCSEL can translate the data into light and emit the light vertically into the PWSI. A first optical coupler can couple the light from the VCSEL to a waveguide which can travel any distance across the PWSI. To accommodate longer paths, the waveguides can be manufactured via reticle stitching, nano imprint lithography, or another suitable fabrication technology. The end of the waveguide can comprise a second optical coupler. The second optical coupler can couple the light from the waveguide to an optical receiver which can convert the optical data to electrical data. The optical receiver can be a separate device, within the second chiplet, and so on. Thus, high bandwidth, high speed photonic communication is enabled across the PWSI.

A front side of the PWSI is bonded to a plurality of chiplets. The chiplets can be connected, attached, bonded, or otherwise coupled to the PWSI 810. In cross-section 800, chiplet 820, chiplet 822, and chiplet 824, are bonded to the front side of the PWSI. The chiplets can include AI accelerators, switching chips, ASICS, I/O chips, and so on. The chiplets can be bonded to the PWSI with micro-bumps, controlled collapse chip connections (C4s), and so on. The bonding can be accomplished via laser-assisted bonding or another bonding method, such as a flip-chip application. The PWSI can include a plurality of through-silicon vias (TSV s) such as TSV 812. A TSV can include an electrical connection that completely passes through a wafer such as a silicon wafer, a glass wafer, or a die. The plurality of TSVs can be oriented vertically in order to enable connections between the front side of the wafer and the back side of the wafer. A chiplet can be coupled to a light source, such as a surface-emitting light source. In embodiments, the surface-emitting light source comprises a vertical-cavity surface-emitting laser (VCSEL). In other embodiments, the surface-emitting light source comprises a light emitting diode (LED). In some embodiments, the surface-emitting light source comprises a laser diode (LD). Other light sources can be used. The PWSI can include one or more surface-emitting light sources such as VCSEL 830 and VCSEL 832.

Data can be sent by a first chiplet to a second chiplet. The sending is based on a first waveguide such as waveguide 860 within the plurality of waveguides on the PWSI. The waveguide can include one or more confinement regions, such as a high confinement region, a low confinement region, and so on. The waveguide can include a transition between confinement regions associated with the waveguide. The transition can include an adiabatic tapering of the waveguide. The second chiplet, such as chiplet 824 can receive the data that was sent. Data from the sending (e.g., first) chiplet can be converted from electrical data, which can be serialized electrical data, to optical data. The optical data can be sent via the waveguide and reconverted to electrical data to be received by the receiving (eg., second) chiplet. In a usage example, the sending includes transmitting the data, by the first chiplet, to a first surface-emitting light source within one or more surface-emitting light sources. The electrical data can be converted to optical data using the surface-emitting light source, such as VCSEL 830.

In order to couple light from a surface-emitting light source to a waveguide, the light is conveyed to an optical coupler. The light that is emitted 840 can be emitted at an angle. In embodiments, the emitting can include angling the light, by an optical element (OE). The angling can be accomplished using a variety of OE techniques. In some embodiments, the OE comprises a micro lens. The OE can comprise a diffractive optical element. In other embodiments, the OE comprises a Fresnel lens. In embodiments, the OE comprises an asymmetric non-focusing optical device.

In order to provide light from a surface-emitting light source to a waveguide, the light, which can be angled, is conveyed to an optical coupler. In embodiments, the optical coupler includes a grating coupler. The optical information can be conveyed as angled light from the first surface-emitting light source, to a first optical coupler 850. The first optical coupler couples the optical information to the first waveguide 860. The optical information is based on the data. The first coupler can be based on one or more coupling techniques. In embodiments, the first optical coupler can include a grating coupler. The grating coupler can diffract light at specific frequencies, thereby providing efficient transfer of light at a specific frequency into or out of a waveguide such as a waveguide within the PWSI. In embodiments, the first optical coupler comprises an off-axis diffractive lens. An off-axis diffractive lens can direct light at an angle with respect to the optical axis of the lens. In embodiments, the first optical coupler includes a bent waveguide. The bent waveguide can include a high containment region of a waveguide. The high containment waveguide can redirect the light while minimizing loss of light in the region of the bend of the waveguide. In embodiments, the first optical coupler comprises a mirror. The mirror can be used to redirect light from the surface-emitting light source into the waveguide. The mirror can comprise a crystallographic etched mirror within the PWSI, such as a tetramethylammonium hydroxide (TMAH) etched mirror. The TMAH mirror can reflect incoming light at a 54.74 degree angle to the first waveguide. Other angles are possible with various crystallographic etched mirrors. A crystallographic etched mirror can operate in combination with a micro-optical element (MOE), which can be placed over or near the laser opening of the VCSEL. For example, the MOE can pre-angle light from the VCSEL so that when the light is reflected by the TMAH mirror, it is efficiently coupled directly into the waveguide at 90 degrees, or sufficiently close to 90 degrees, from the light source. In embodiments, the MOE comprises a micro lens. In other embodiments, the MOE comprises a diffractive optical element. In some embodiments, the MOE comprises a Fresnel lens. In embodiments, the MOE comprises an asymmetric non-focusing optical device.

The second chiplet 822 can receive the data that was sent. The receiving can include coupling the optical information, using a second optical coupler, from the first waveguide to an optical receiver. The second optical coupler can be based on one or more receiving techniques. The second optical coupler can comprise a grating coupler. The second grating coupler can diffract light at specific frequencies to enable efficient transfer of light out of a waveguide within the PWSI. The second optical coupler can comprise a photodiode. The photodiode can convert the optical data to digital data. The data received at the optical coupler can be transferred. The data can be transferred by the optical receiver to the second chiplet. The data that is transferred can be transferred as optical data or transferred as digital data. The data can be received at the second chiplet by a receiver 870. If the receiver receives optical data, the receiver can convert the optical data to digital data. If the receiver receives digital data, the digital data can be used as received, converted from serial data to parallel data, and so on.

A plurality of modular power substrates can be included with the PWSI. Embodiments include coupling, to the back side of the PWSI, a plurality of modular power substrates (MPSs). In the cross-section 800, the plurality of MPSs can include MPS 880. The MPSs can be further coupled to a plurality of DC-to-DC converters (not shown in cross-section 800). The plurality of DC-to-DC converters can comprise a unified control board (UCB). The coupling of the MPSs to the PWSI can be achieved by a number of techniques. The MPSs can be bonded to a back side of the PWSI by laser-assisted bonding (LAB). The LAB can create localized heat at points, by one or more lasers, on the PWSI where the MPSs are bonded to the PWSI. The bonding can be accomplished using solder balls 882 such as microbumps, controlled collapse chip connections (C4s), ball grid arrays (BGAs), and so on. The bonding of the MPSs to the PWSI can include bonding the MPSs to one or more through-silicon vias (TSVs) such as TSV 812. The laser-assisted bonding is able to create heat at the solder balls without heating the PWSI using a reflow soldering technique. It can be advantageous to avoid heating the PWSI, as heating the PWSI using a reflow technique can cause previously soldered connections to reflow and potentially disconnect or short, damaging diffusions, waveguides, and so on.

The MPSs can be coupled to a back side of the PWSI via one or more elastomer sheets (not shown in cross-section 800). The elastomer sheet can comprise a conductive filament, such as brass, gold, etc., embedded in a silicone rubber sheet, or another suitable material. The filaments can be embedded on a pitch. The pitch can be designed to match a connector array, such as a ball grid array (BGA), of the MPS. The elastomer sheet can be held in place with a compression force which can be delivered by one or more compression plates (not shown in cross-section 800). An adhesive backing can be added to the elastomer sheet. When one or more filaments come in contact with a C4, contact can be made between the C4 of the MPS and a solder bump, microbump, or a C4 associated with the PWSI. One or more filaments can make contact with one or more TSVs. Once coupled to the back side of the PWSI, the MPSs can send power to the chiplets.

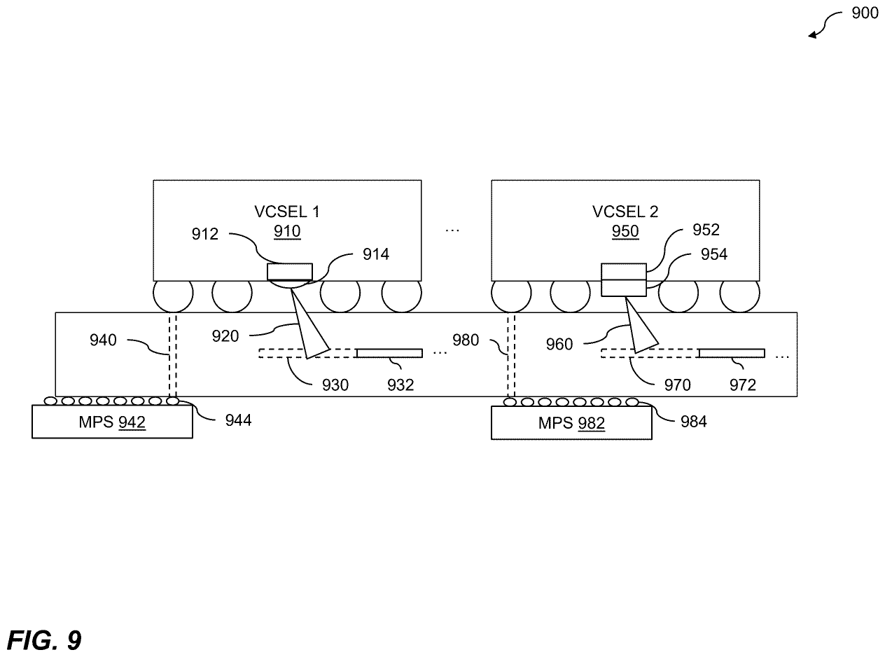

FIG. 9 is a cross-section of a photonic wafer-scale interposer with an angled beam grating coupler. The PWSI can include a plurality of waveguides that can be used to enable highspeed communication between chiplets bonded to a front side of the PWSI. A surface-emitting light is used to emit light based on data to be sent from a first chiplet to a second chiplet. The data can include serial data. The emitted light can be coupled to a waveguide, which can transfer the light as optical data. The coupling to the waveguide can be accomplished using a grating coupler. An optical detector at the far end of the waveguide can detect the light that was transferred via the waveguide. The optical detector, such as a photodiode, can transfer the data to the second chiplet. The second chiplet thereby receives the data that was sent. The sending data is enabled by a photonic wafer-scale interposer with angled beam grating couplers.

The cross-section 900 shows two example techniques for emitting, at an angle, light from a first surface-emitting light source. In embodiments, the first surface-emitting light source can include a first vertical-cavity surface-emitting laser (VCSEL). In the figure, two VCSELs are shown, VCSEL 1 910 and VCSEL 2 950. The light emitted can include wavelengths of light within a range of wavelengths. In a nonlimiting usage example, the VCSEL can emit light at a wavelength between 750 nm and 980 nm. Proceeding with VCSEL 1 910, the VCSEL can include an aperture 912. Light emitted by the VCSEL can exit the VCSEL via the aperture. The emitted light can be angled. The angling the light can be accomplished using an optical element (OE). In embodiments, the OE can be coupled to the first VCSEL. The OE can include a lens, a diffractive lens, an optical device, and so on. In embodiments, the OE includes a micro lens 914. The light that is angled by the micro lens can be directed 920 at a grating coupler 930. The grating coupler can be “tuned” to couple light at the wavelength of light emitted by the VCSEL. The grating coupler can couple light into a first waveguide 932. The VCSEL 910 requires power such as DC power to operate. The DC power can be provided by a modular power substrate (MPS) such as MPS 942. The MPS can be coupled to the PWSI using an elastomer sheet, microbumps, etc. In the cross-section 900, the MPS can be coupled to the PWSI using microbumps or C4s 944. The MPS can be coupled to through-silicon via (TSV) associated with the PWSI. In the figure, MPS 942 is coupled to VCSEL 1 via TSV 940.

A second example VCSEL configuration can include VCSEL 2 950. Light emitted by VCSEL 2 exits at an aperture 952. The light emitted by VCSEL 2 at the aperture can be angled by a OE 954. The OE can include a diffractive element. In embodiments, the OE can include a Fresnel lens. In other embodiments, the OE can include an asymmetric non-focusing optical device. The light angled 960 by the Fresnel lens, or another OE, can be directed at a grating coupler 970. The grating coupler can couple the emitted light into a waveguide 972. As for V CSEL 1, VCSEL 2 requires DC power to operate. The DC power can be provided by an MPS 982. The MPS can be coupled 984 to the PWSI using an elastomer sheet, micro bumps, C4s, solder balls associated with a ball grid array (BGA), and the like. The DC power from the MPS can be transferred to VCSEL 2 using one or more TSVs 980.

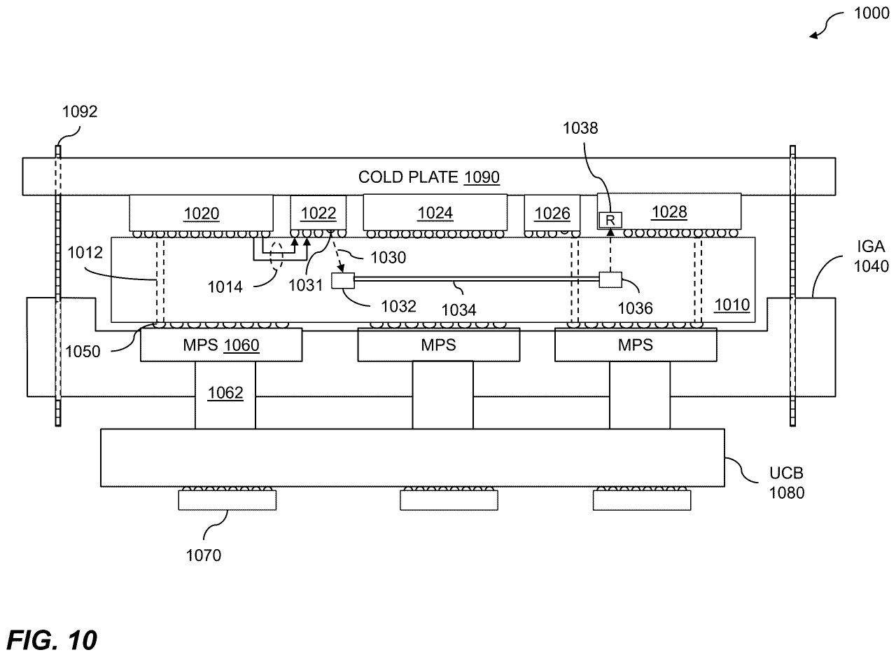

FIG. 10 is an apparatus for a photonic wafer-scale interposer with angled beam grating couplers. A variety of electronic and photonic elements can be attached, bonded, mounted, or otherwise coupled to a photonic wafer-scale interposer (PWSI). The variety of elements can include chiplets such as switching chiplets, AI accelerators, and so on. Power such as DC power can be sent by a plurality of DC-to-DC converters, which can comprise a universal control board (UCB), to a plurality of elements including chiplets. The sending can be accomplished using a plurality of modular power substrates (MPSs), and a plurality of through-silicon vias (TSVs). The plurality of photonic elements, chiplets, etc. can be bonded to a front side of a photonic wafer-scale interposer (PWSI). The plurality of MPSs can be coupled to the back side of the PWSI. The MPSs can also be coupled to the UCB based on a plurality of high-power sockets. The coupling of the MPSs to the back side of the PWSI can be based on laser-assisted bonding techniques. Alternatively, the plurality of MPSs can be coupled to a back side of the PWSI based on a plurality of conductive elastomer sheets. The elastomer sheets can provide adhesion between the MPSs and the PWSI. The elastomer sheets can provide conduction paths between the MPSs and the PWSI. The conductive paths can include filaments of copper, silver, and so on. The elastomer sheets can be compressed by an isometric grid array (IGA). The IGA can comprise a compression plate. One or more additional compression plates can be added. The IGA can be stiffened based on a plurality of reinforcements such as reinforcement crossbars, reinforcement rings, etc. The stiffening can accomplish one or more goals associated with the apparatus. The stiffening can enable planar compression of the elastomer sheet. In embodiments, the planar compression is based on the one or more spring-loaded fasteners. The planar compression can be based on one or more clamps. The planar compression can enable consistent adhesion of the MPSs to a back side of the PWSI. The planar compression can further enable reliable coupling of conduction paths through the conductive connecting material to contacts, pads, etc. associated with the MPSs and the PWSI.

An apparatus for sending data is disclosed comprising: a photonic wafer-scale interposer (PWSI), wherein the PWSI includes a plurality of waveguides; a plurality of chiplets, wherein the plurality of chiplets is bonded to a front side of the PWSI, wherein the plurality of chiplets includes at least one surface-emitting light source, a first chiplet, and a second chiplet; an optical element (OE), wherein the OE angles light, from a first surface-emitting light source within the at least one first surface-emitting light source; and a grating coupler within the PWSI, wherein the grating coupler couples light that was angled from the first surface-emitting light source, to a first waveguide within the plurality of waveguides.

The apparatus 1000 includes a photonic wafer-scale interposer (PWSI) 1010, wherein the PWSI includes a plurality of waveguides. The plurality of waveguides can be used to enable highspeed communications between and among various elements that can be bonded, attached, or otherwise coupled to the PWSI. The apparatus 1000 can include a plurality of through silicon vias (TSV s) such as TSV 1012. The plurality of through-silicon vias (TSV s) associated with the PWSI can be used to provide connections between a front side of the PWSI and a back side of the PWSI. The PWSI can be used to achieve wafer-scale integration (WSI), based on a photonic wafer-scale interposer with angled beam grating couplers. The PWSI can be used to mount various elements such as electrical elements, optical elements, electro-optical elements, and so on. The PWSI can further provide interconnections among the mounted elements, and waveguides within the PWSI, to transfer optical data. The PWSI can include inorganic materials or organic materials. In a usage example, the PWSI can include a silicon interposer. Micro-bumps discussed above can be used to mount the one or more chiplets, such as chiplets 1020, 1024, and 1028 to the front side of the PWSI.

The apparatus 1000 includes a plurality of chiplets, wherein the plurality of chiplets is bonded to a front side of the PWSI, wherein the plurality of chiplets includes at least one surface-emitting light source, a first chiplet, and a second chiplet. Example surface-emitting light sources can include surface-emitting light source 1022 and surface-emitting light source 1026. In embodiments, the at least one surface-emitting light source comprises at least one vertical-cavity surface-emitting laser (VCSEL). A surface-emitting light source can include an LED, laser diode, and so on. A second surface-emitting light source is shown 1026. Microbumps can also be used to attach one or more surface-emitting light sources. The plurality of chiplets, such as the first chiplet and the second chiplet can include chiplet 1020, chiplet 1024, and chiplet 1028. The plurality of chiplets can include one or more processor chips, multi-core processor chips, graphics processor chips, systems-on-a-chip (SoCs), memory chips, I/O chips, ASICs, artificial intelligence (AI) or machine learning (ML) accelerators, and so on. The first chiplet 1020 can transmit data to the first surface-emitting light source 1022. The first surface-emitting light source can be used to transfer data between the first chiplet and the second chiplet. The surface-emitting light source can be used to convert digital data such as serial digital data to optical data. The optical data can include serial optical data.

The chiplets can include an integrated circuit designed for a flip-chip application. The chiplets can include a chip that can accomplish a processing function such as a deep learning function, a network switching function, and so on. In embodiments, the PWSI can include an optical wafer-scale AI accelerator, wherein one or more chiplets within the plurality of chiplets can include one or more artificial intelligence (AI) accelerators. The PWSI can be configured for other processing, networking, and further applications. In embodiments, the PWSI can include an optical wafer-scale network switch, wherein one or more chiplets within the plurality of chiplets can include one or more switching chiplets. In embodiments, the plurality of chiplets can include one or more I/O chiplets.

Communications between the chiplets and the surface-emitting light sources can be accomplished within metal layers of the interposer. In embodiments, the sending data can be based on one or more metal layers within the PWSI. The first chiplet 1020 can be coupled to the first surface-emitting light source 1022 via interposer wires 1014. Use of wiring within the PWSI reduces latency and parasitics such as resistance, capacitance, and inductance, and enables improvement of signal integrity and/or bandwidth, etc. Optical data from the surface-emitting light source can be coupled to a waveguide within the PWSI. The optical data from the surface-emitting light source can be conveyed 1030 to an optical coupler. The apparatus 1000 includes an optical element (OE) 1031, wherein the OE angles light, from a first surface-emitting light source within the at least one first surface-emitting light source. The OE can angle light at an angle different from 90 degrees. In embodiments, the angling can result in an acute angle to the grating coupler. In a usage example, the OE can angle the light at an angle of 54.7 with respect to the surface of the PWSI. The apparatus 1000 includes a grating coupler 1032 within the PWSI, wherein the grating coupler couples light that was angled from the first surface-emitting light source, to a first waveguide 1034 within the plurality of waveguides. The angled light that is coupled can be based on the data. The optical coupler can include an off-axis diffractive lens, a mirror, a bent waveguide, and the like. The waveguide can include a tapered waveguide. The waveguide can be tapered using a variety of techniques. The tapering the waveguide can be accomplished using adiabatic tapering, three-dimensional (3D) lithography, grayscale lithography, and so on.

The apparatus 1000 can include a second optical coupler 1036. The second optical coupler can couple the optical information from the first waveguide. The second optical coupler can be based on a grating coupler, a photodiode, a photo Darlington, and the like. A receiver 1038 can be coupled to the second optical coupler. The second optical coupler can couple the optical information from the waveguide to the receiver. In a usage example, the receiver can include an optical receiver to receive optical data from an optical coupler. The receiver can receive electronic data when the receiver includes an electronic device such as a photodiode. The receiver can transfer the data to the second chiplet 1028. Thus, digital data can be sent from the first chiplet to the second chiplet by converting the digital data to optical data, coupling the optical data to a waveguide, and receiving the optical data at a receiver that converts the optical data to digital data, and transfers the digital data to the second chiplet. The sending data optically between chiplets can significantly reduce data transfer latency and can improve data integrity. Thus, the PWSI can enable extremely high bandwidth buses and control signals between chiplets mounted to the PWSI. The PWSI can include one or more optical waveguides. The optical waveguides can enable chiplet-to-chiplet communications via one or more wavelengths of light. The optical waveguides can comprise the buses and control signals between chiplets. The photonic interposer can also be used to attach additional boards, modules, components, and so on. The further attachments can be located on the opposite side of the PWSI from the mounted chiplets and surface-emitting light sources.

The apparatus 1000 can include an isometric grid array (IGA) 1040. The IGA can enable support of and stiffening of the photonic wafer-scale interposer. Recall that the PWSI can be ground and polished to a thinness that is able to support the TSVs. As a result, the PWSI can deflect under the weight of the components that can be bonded and coupled to it. The IGA can support and planarize the PWSI, thereby preventing the PWSI from fracturing. The IGA can include a plurality of reinforcement structures.

The apparatus 1000 can include a plurality of modular power substrates (MPSs), such as MPS 1060. The MPSs can be inserted through a grid within the IGA. Each MPS can be coupled to the back side of the PWSI. The coupling can be based on microbumps, C4s 1050, and the like. The coupling can be based on laser-assisted bonding which can reflow the C4's microbumps, etc. without disturbing other bonded components. The coupling can be based on elastomer sheets or another coupling method. Each MPS within the plurality of MPSs can include a connector. For the apparatus 1000, a connector can comprise a socket 1062. The socket can comprise a high-power socket, a high voltage socket, and so on. One or more plugs, pins, terminals, contacts, etc. from a unified control board (UCB) can be inserted into the socket. The high voltage socket can be used to provide a first DC voltage. The first DC voltage can be provided by a DC-to-DC converter. The first DC voltage can be converted to a second DC voltage by one or more DC-to-DC converters. The coupling of the MPSs to the PWSI can accommodate a difference in maximum lateral displacement due to various coefficients of thermal expansion of elements such as the PWSI, IGA, UCB, and so on. The lateral displacement can result from thermal expansion of the PWSI, the UCB, and/or the MPS during operation.

The apparatus 1000 can include a plurality of DC-to-DC converters such as DC-to-DC converter 1070. The plurality of DC-to-DC power converters can comprise a unified control board (UCB) 1080. The DC-to-DC converters can be coupled to the UCB, wherein the coupling can be based on the plurality of sockets. The UCB can be coupled to the plurality of MPSs. The UCB can send DC power to the plurality of chiplets bonded to the PWSI. The sending can be based on the plurality of MPSs and the plurality of TSV s such as TSV 1012.

The UCB 1080 can include a digital controller chip (not shown). The DC-to-DC converters can be controlled by a control chip associated with the UCB. The digital controller chip can control power delivery to the plurality of functional chips. The controlling power delivery can include enabling or disabling power transfer, controlling an input voltage to an output voltage from a DC-to-DC converter, and the like. A usage example can include matching each DC-to-DC power converter within the plurality of DC-to-DC power converters included on the UCB to one or more respective MPSs in the plurality of MPSs. DC power from a DC-to-DC converter can be sent to an MPS via an interconnect on the UCB. DC power can be fed to the DC-to-DC converters. The control signals can enable and disable elements such as controller chips and DC-to-DC converters, can provide instructions to controller chips, etc. As explained above and throughout, the PWSI and the UCB can expand at different rates due to different CTEs. Thus, the MPSs that are coupled to the UCB can also move, which can cause connections associated with the elastomer sheets between the PWSI and the MPSs to become unreliable. To mitigate this movement due to expansion, as explained previously, the MPS can be designed modularly, effectively isolating movement between MPSs. In addition, the socket, which can be a high-power socket, a high voltage socket, etc., can comprise a compliant connector.

An MPS, such as MPS 1060 can include a plurality of step-down power modules and/or DC-to-DC power converters. The DC-to-DC converters on an MPS can be placed across the MPS. The DC-to-DC power converters on the MPSs can accomplish altering of a DC voltage. The altering the DC voltage can result in a second DC voltage. In a usage example, the power can be altered, wherein altering, by the plurality of MPSs, is accomplished by the DC power that was sent, and wherein the altering is based on a second voltage conversion. The second voltage conversion can include a second DC-to-DC voltage conversion. In embodiments, the second voltage conversion results in a voltage less than a threshold. The threshold can include a voltage appropriate to a voltage required by a functional chip. In embodiments, the threshold can include 1 volt.

The apparatus 1000 can include a cold plate 1090. The cold plate can be coupled to one or more chiplets, surface-emitting light sources, etc. The cold plate can be mounted to an isometric grid array (IGA) (described above). The cold plate can be used to extract a portion of heat generated by chiplets, light sources, and other elements as the functional chiplets etc. operate. Recall that prodigious amounts of heat can be generated by chips and other electronic elements as they are operating. This point can be particularly relevant to high-performance chips. The mounting of the cold plate to a grid such as the IGA can be accomplished using clips, screws, bolts, clamps, and so on. For the apparatus, the cold plate can be mounted to the IGA using clamps such as clamp 1092.

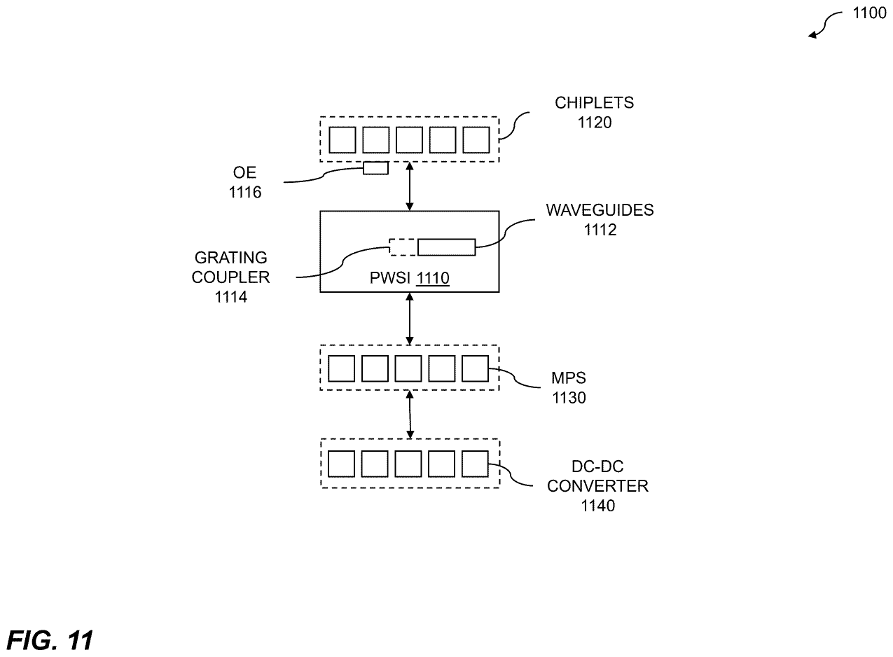

FIG. 11 is a system diagram for a photonic wafer-scale interposer with angled beam grating couplers. A plurality of waveguides can be formed within the PWSI. The waveguides can enable high-speed communication with chiplets bonded to a front side of the PWSI. Data that is transferred between the chips can include digital data such as serial electronic data. The electronic data can be converted at a first chiplet to optical data in order to be transferred to a second chiplet using a waveguide. The optical data can be received at the second chiplet and can be converted to electronic data. Disclosed is a system for sending data comprising: a photonic wafer-scale interposer (PWSI); a plurality of chiplets; an optical element (OE); and a grating coupler within the PWSI, wherein the system is configured to: use the PWSI, wherein a front side of the PWSI is bonded to the plurality of chiplets, wherein the plurality of chiplets includes at least one surface-emitting light source, a first chiplet, and a second chiplet, and wherein the PWSI includes a plurality of waveguides; send data, by the first chiplet, to a first surface-emitting light source within the at least one surface-emitting light source; emit light, by the first surface-emitting light source, wherein the light that was emitted is based on the data that was sent, and wherein emitting includes angling the light, by the OE; couple, by the grating coupler within the PWSI, the light that was angled from the first surface-emitting light source, to a first waveguide within the plurality of waveguides; and receive, by the second chiplet, the data that was sent, wherein the receiving is based on the light that was coupled to the first waveguide.

The system 1100 is configured to use a PWSI 1110, wherein a front side of the PWSI is bonded to the plurality of chiplets 1120, wherein the plurality of chiplets includes at least one surface-emitting light source, a first chiplet, and a second chiplet, and wherein the PWSI includes a plurality of waveguides 1112. The PWSI can further include a plurality of through-silicon vias (TSVs). The PWSI can comprise an inorganic wafer such as a silicon wafer, within which waveguides can be fabricated. The plurality of waveguides can enable highspeed communication between chiplets within the plurality of chiplets.

The plurality of chiplets can include switching chiplets, surface-emitting light sources, general purpose chiplets, A SICs, AI accelerators, etc. The chiplets can further include optical light sources including surface-emitting light sources. The surface-emitting light sources can include vertical-cavity surface-emitting lasers (VCSELs), light emitting diodes (LEDs), laser diodes, and so on. The chiplets, surface-emitting light sources, and other elements can create prodigious heat during operation. The heat can be due to current provided to the chiplets such as active current, overcurrent, leakage current, and so on. The heat can result from IR drops associated with interconnect, active devices, leakage current, etc. within the chiplets. The chiplets can be bonded to the PWSI via micro-bumps, controlled collapse chip connections (C4s), and so on. The PWSI can include a plurality of through-silicon vias (TSVs) (not shown). A TSV can include an electrical connection that completely passes through a wafer such as a silicon wafer or a die. The plurality of TSVs can be oriented vertically in order to enable connections between the front side of the wafer and the back side of the wafer.

The system 1100 is configured to send data, by the first chiplet, to a first surface-emitting light source within the at least one surface-emitting light source. The sending of the data can be based on one or more wire paths fabricated within, on, etc. the PWSI. In embodiments, the at least one surface-emitting light source comprises at least one vertical-cavity surface-emitting laser (VCSEL). The system 1100 includes an optical element (OE) 1116. The system 1100 is further configured to emit light, by the first surface-emitting light source, wherein the light that was emitted is based on the data that was sent, and wherein emitting includes angling the light, by the OE. The OE can include a micro lens, a Fresnel lens, an asymmetric non-focusing optical device, and so on. The OE can cause light received by the OE to be angled. In embodiments, the angling can result in an acute angle to a grating coupler (described below). The angling by the OE of the light directed to the grating coupler can enhance or increase an amount of light transferred by the grating into the waveguide.

The system 1100 includes a grating coupler 1114. The grating coupler can be fabricated to capture a frequency of light. The grating coupler can couple light received from a light source into a waveguide. The system 1100 is further configured to couple, by the grating coupler within the PWSI, the light that was angled from the first surface-emitting light source, to a first waveguide within the plurality of waveguides.

The system 1100 is further configured to receive, by the second chiplet, the data that was sent, wherein the receiving is based on the light that was coupled to the first waveguide. Thus, high speed and high bandwidth data movement is enabled by the system. Note that any two chiplets on the PWSI can share information via the disclosed methods. Thus, extremely high bandwidth cross-wafer communication is enabled.

The system 1100 can include a plurality of modular power substrates (MPSs) 1130. The plurality of MPSs can be coupled to a back side of the PWSI by a plurality of elastomer sheets, by laser-assisted bonding, or by another coupling method. Each MPS within the plurality of MPSs can be based on a form factor mirroring one or more corresponding chiplets within the plurality of chiplets on the front side of the PWSI. The system 1100 can include an isometric grid array (IGA) (not shown). The IGA can include a plurality of open recesses, a plurality of reinforcement structures, and so on. The IGA and each reinforcement structure within the plurality of reinforcement structures can accomplish stiffening of each MPS in the plurality of MPSs. The PWSI can be compressed by the IGA and a cold plate. The cold plate can be used to remove a portion of the heat generated by the plurality of chiplets. In embodiments, the compressing can maintain a coplanarity of the PWSI. Maintaining coplanarity of the PWSI can reduce the risk of the PWSI fracturing or cracking under pressure applied by the IGA.

The system 1100 can include one or more DC-to-DC converters 1140. The one or more DC-to-DC converters can comprise a unified control board (UCB). The MPSs can be coupled to the UCB via a high voltage socket, a high voltage connector, and so on. Power can be delivered to the chiplets via the DC-to-DC converters. Embodiments include delivering DC power, by the UCB, to the plurality of chiplets, wherein the delivering is based on the plurality of DC-to-DC power converters, the plurality of MPSs, and the plurality of TSV s, and wherein the delivering includes a first voltage conversion. Further embodiments include transferring the DC power that was delivered, by the plurality of MPSs, to the plurality of chiplets, wherein the transferring includes a second voltage conversion.

Each of the above methods may be executed on one or more processors on one or more computer systems. Embodiments may include various forms of distributed computing, client/server computing, and cloud-based computing. Further, it will be understood that the depicted steps or boxes contained in this disclosure's flow charts are solely illustrative and explanatory. The steps may be modified, omitted, repeated, or re-ordered without departing from the scope of this disclosure. Further, each step may contain one or more sub-steps. While the foregoing drawings and description set forth functional aspects of the disclosed systems, no particular implementation or arrangement of software and/or hardware should be inferred from these descriptions unless explicitly stated or otherwise clear from the context. All such arrangements of software and/or hardware are intended to fall within the scope of this disclosure.

The block diagram and flow diagram illustrations depict methods, apparatus, systems, and computer program products. The elements and combinations of elements in the block diagrams and flow diagrams show functions, steps, or groups of steps of the methods, apparatus, systems, computer program products and/or computer-implemented methods. Any and all such functions—generally referred to herein as a “circuit,” “module,” or “system”—may be implemented by computer program instructions, by special-purpose hardware-based computer systems, by combinations of special purpose hardware and computer instructions, by combinations of general-purpose hardware and computer instructions, and so on.

A programmable apparatus which executes any of the above-mentioned computer program products or computer-implemented methods may include one or more microprocessors, microcontrollers, embedded microcontrollers, programmable digital signal processors, programmable devices, programmable gate arrays, programmable array logic, memory devices, application specific integrated circuits, or the like. Each may be suitably employed or configured to process computer program instructions, execute computer logic, store computer data, and so on.

It will be understood that a computer may include a computer program product from a computer-readable storage medium and that this medium may be internal or external, removable and replaceable, or fixed. In addition, a computer may include a Basic Input/Output System (BIOS), firmware, an operating system, a database, or the like that may include, interface with, or support the software and hardware described herein.

Embodiments of the present invention are limited to neither conventional computer applications nor the programmable apparatus that run them. To illustrate: the embodiments of the presently claimed invention could include an optical computer, quantum computer, analog computer, or the like. A computer program may be loaded onto a computer to produce a particular machine that may perform any and all of the depicted functions. This particular machine provides a means for carrying out any and all of the depicted functions.

Any combination of one or more computer readable media may be utilized including but not limited to: a non-transitory computer readable medium for storage; an electronic, magnetic, optical, electromagnetic, infrared, or semiconductor computer readable storage medium or any suitable combination of the foregoing; a portable computer diskette; a hard disk; a random access memory (RAM); a read-only memory (ROM); an erasable programmable read-only memory (EPROM, Flash, M RAM, FeRAM, or phase change memory); an optical fiber; a portable compact disc; an optical storage device; a magnetic storage device; or any suitable combination of the foregoing. In the context of this document, a computer readable storage medium may be any tangible medium that can contain or store a program for use by or in connection with an instruction execution system, apparatus, or device.

It will be appreciated that computer program instructions may include computer executable code. A variety of languages for expressing computer program instructions may include without limitation C, C++, Java, JavaScript™, ActionScript™, assembly language, Lisp, Perl, Tcl, Python, Ruby, hardware description languages, database programming languages, functional programming languages, imperative programming languages, and so on. In embodiments, computer program instructions may be stored, compiled, or interpreted to run on a computer, a programmable data processing apparatus, a heterogeneous combination of processors or processor architectures, and so on. Without limitation, embodiments of the present invention may take the form of web-based computer software, which includes client/server software, software-as-a-service, peer-to-peer software, or the like.

In embodiments, a computer may enable execution of computer program instructions including multiple programs or threads. The multiple programs or threads may be processed approximately simultaneously to enhance utilization of the processor and to facilitate substantially simultaneous functions. By way of implementation, any and all methods, program codes, program instructions, and the like described herein may be implemented in one or more threads which may in turn spawn other threads, which may themselves have priorities associated with them. In some embodiments, a computer may process these threads based on priority or other order.

Unless explicitly stated or otherwise clear from the context, the verbs “execute” and “process” may be used interchangeably to indicate execute, process, interpret, compile, assemble, link, load, or a combination of the foregoing. Therefore, embodiments that execute or process computer program instructions, computer-executable code, or the like may act upon the instructions or code in any and all of the ways described. Further, the method steps shown are intended to include any suitable method of causing one or more parties or entities to perform the steps. The parties performing a step, or portion of a step, need not be located within a particular geographic location or country boundary. For instance, if an entity located within the United States causes a method step, or portion thereof, to be performed outside of the United States, then the method is considered to be performed in the United States by virtue of the causal entity.

While the invention has been disclosed in connection with preferred embodiments shown and described in detail, various modifications and improvements thereon will become apparent to those skilled in the art. Accordingly, the foregoing examples should not limit the spirit and scope of the present invention; rather it should be understood in the broadest sense allowable by law.

What is claimed is:

1. A method for sending data comprising:
accessing a photonic wafer-scale interposer (PWSI), wherein a front side of the PWSI is bonded to a plurality of chiplets, wherein the plurality of chiplets includes at least one surface-emitting light source, a first chiplet, and a second chiplet, and wherein the PWSI includes a plurality of waveguides;
sending data, by the first chiplet, to a first surface-emitting light source within the at least one surface-emitting light source;
emitting light, by the first surface-emitting light source, wherein the light that was emitted is based on the data that was sent, and wherein the emitting includes angling the light, by an optical element (OE);
coupling, by a grating coupler within the PWSI, the light that was angled from the first surface-emitting light source, to a first waveguide within the plurality of waveguides; and
receiving, by the second chiplet, the data that was sent, wherein the receiving is based on the light that was coupled to the first waveguide.

2. The method of claim 1 wherein the OE comprises a micro lens.

3. The method of claim 1 wherein the OE comprises a Fresnel lens.

4. The method of claim 1 wherein the OE comprises an asymmetric non-focusing optical device.

5. The method of claim 1 wherein the first surface-emitting light source comprises a first vertical-cavity surface-emitting laser (VCSEL).

6. The method of claim 5 wherein the OE is coupled to the first VCSEL.

7. The method of claim 6 wherein the angling results in an acute angle to the grating coupler.

8. The method of claim 1 wherein the sending data is based on one or more metal layers within the PWSI.

9. The method of claim 1 wherein the plurality of chiplets includes one or more I/O chiplets.

10. The method of claim 1 wherein the PWSI comprises an optical wafer-scale AI accelerator, wherein one or more chiplets within the plurality of chiplets comprise one or more artificial intelligence (AI) accelerators.

11. The method of claim 1 wherein the PWSI comprises an optical wafer-scale network switch, wherein one or more chiplets within the plurality of chiplets comprise one or more switching chiplets.

12. The method of claim 1 further comprising providing power to the plurality of chiplets, wherein the providing is based on a back side of the PWSI, and wherein the PWSI includes a plurality of through-silicon vias (TSV s).

13. The method of claim 12 further comprising coupling, to the back side of the PWSI, a plurality of modular power substrates (MPSs).

14. The method of claim 13 wherein the coupling is accomplished via one or more elastomer sheets.

15. The method of claim 13 wherein the coupling is accomplished via laser-assisted bonding (LAB).

16. The method of claim 13 further comprising inserting each MPS within the plurality of MPSs that was coupled into an isometric grid array (IGA), wherein the IGA includes a plurality of open recesses.

17. The method of claim 16 wherein the plurality of open recesses comprises a grid, wherein the IGA contacts the back side of the PWSI between each MPS within the plurality of MPSs that were bonded.

18. The method of claim 17 further comprising mounting the IGA to a cold plate, wherein the cold plate contacts the plurality of chiplets bonded to the front side of the PWSI.

19. The method of claim 18 wherein the mounting is based on one or more spring-loaded fasteners.

20. The method of claim 18 wherein the mounting is based on one or more clamps.

21. The method of claim 20 further comprising compressing the PWSI, wherein the compressing is based on the mounting, and wherein the compressing maintains a coplanarity of the PWSI.

22. The method of claim 16 further comprising coupling the plurality of MPSs to a plurality of DC-to-DC power converters.

23. The method of claim 22 wherein the plurality of DC-to-DC power converters comprises a unified control board (UCB), wherein the coupling is based on a plurality of sockets.

24. The method of claim 23 further comprising delivering DC power, by the UCB, to the plurality of chiplets, wherein the delivering is based on the plurality of DC-to-DC power converters, the plurality of MPSs, and the plurality of TSVs, and wherein the delivering includes a first voltage conversion.

25. The method of claim 24 further comprising transferring the DC power that was delivered, by the plurality of MPSs, to the plurality of chiplets, wherein the transferring includes a second voltage conversion.

26. An apparatus for sending data comprising:
a photonic wafer-scale interposer (PWSI), wherein the PWSI includes a plurality of waveguides;
a plurality of chiplets, wherein the plurality of chiplets is bonded to a front side of the PWSI, wherein the plurality of chiplets includes at least one surface-emitting light source, a first chiplet, and a second chiplet;
an optical element (OE), wherein the OE angles light, from a first surface-emitting light source within the at least one surface-emitting light sources; and
a grating coupler within the PWSI, wherein the grating coupler couples light that was angled from the first surface-emitting light source, to a first waveguide within the plurality of waveguides.

27. The apparatus of claim 26 wherein the at least one surface-emitting light source comprises at least one vertical-cavity surface-emitting laser (VCSEL).

28. A system for sending data comprising:
a photonic wafer-scale interposer (PWSI);
a plurality of chiplets;
an optical element (OE); and
a grating coupler within the PWSI, wherein the system is configured to:
use the PWSI, wherein a front side of the PWSI is bonded to the plurality of chiplets, wherein the plurality of chiplets includes at least one surface-emitting light source, a first chiplet, and a second chiplet, and wherein the PWSI includes a plurality of waveguides;
send data, by the first chiplet, to a first surface-emitting light source within the at least one surface-emitting light source;
emit light, by the first surface-emitting light source, wherein the light that was emitted is based on the data that was sent, and wherein emitting includes angling the light, by the OE;
couple, by the grating coupler within the PWSI, the light that was angled from the first surface-emitting light source, to a first waveguide within the plurality of waveguides; and
receive, by the second chiplet, the data that was sent, wherein the receiving is based on the light that was coupled to the first waveguide.
